(19) United States
(12) Patent Application Publication
(10) Pub. No.: US 2026/0020485 A1
(43) Pub. Date: Jan. 15, 2026

(54) DISPLAY PANEL AND DISPLAY DEVICE

(71) Applicant: BOE TECHNOLOGY GROUP CO. , LTD., Beijing (CN)

(72) Inventors: Haiyan SUN, Beijing (CN); Xiaojin ZHANG, Beijing (CN); Dan WANG, Beijing (CN)

(21) Appl. No.: 18/996,107

(22) PCT Filed: Mar. 31, 2023
(86) PCT No.: PCT/CN2023/085571

§ 371 Date: Jan. 17, 2025

(51) Int. Cl. H10K 59/80; H10K 59/35

(52) U.S. Cl. CPC H10K 59/8791; H10K 59/353

(57) ABSTRACT

Embodiments of the present disclosure provide a display panel and a display device, the display panel includes sub-pixels arranged in an array, and includes: a base substrate, a light-emitting device layer, an optical adjustment layer, and an antireflection layer; the light-emitting device layer includes a first light-emitting region configured to emit light with a first color and in a first wavelength range, and a second light-emitting region configured to emit light with a second color and in a second wavelength range; the optical adjustment layer is disposed on a light exiting side of the light-emitting device layer, and configured to have a transmittance for light in the first wavelength range being smaller than a transmittance thereof for light in the second wavelength range, and to have a reflectivity for light in the first wavelength range being greater than a reflectivity thereof for light in the second wavelength range.

### TECHNICAL FIELD

Embodiments of the present disclosure relate to a display panel and a display device.

### BACKGROUND

Organic light-emitting diode (OLED) display panel is widely used in the display field for its advantages such as self-luminescence, wide viewing angle and fast response. An OLED display panel usually includes light-emitting devices with light-emitting layers for emitting light of different colors (e.g., red color, green color, blue color). Generally speaking, in the existing light-emitting devices, phosphorescent materials are commonly used as red and green light-emitting materials, while fluorescent materials are usually used as blue light-emitting materials due to issues of lifespan. Then, due to the difference between luminescence mechanisms of phosphorescence and fluorescent materials themselves, the luminescence efficiency of fluorescence material is much lower than that of phosphorescence material, which in turn leads to the light extraction efficiency and luminous brightness of blue light-emitting regions in the display panel being much lower than those of red and green light-emitting regions. Therefore, improving the light extraction efficiency of blue light is an important research topic of existing OLED display technology.

In order to improve the light extraction efficiency in blue light-emitting regions, most of the existing technical solutions aim at optimizing the luminescence mechanisms of blue light materials to achieve the device performance of red and green light. However, at present, most of the new luminescence mechanisms for blue light cannot achieve both efficiency and lifespan, which cannot satisfy the demand of mass production. Therefore, in order to ensure the display lifespan of blue light, the existing display technology generally increases the display area of the blue sub-pixel and reduces the current density, thus ensuring the effective lifespan of blue light. However, this will also lead to the decrease of pixel density and the decrease of fineness of display image. Moreover, since there is an upper limit of the spacing between display units due to process limit, it will also lead to an increase in process difficulty, which in turn will lead to a decrease in product yield.

### SUMMARY

At least one embodiment of the present disclosure provides a display panel, including a plurality of sub-pixels arranged in an array, and including: a base substrate; a light-emitting device layer, disposed on a side of the base substrate, wherein the light-emitting device layer includes a plurality of light-emitting regions configured to emit light of different colors, the plurality of light-emitting regions respectively correspond to the plurality of sub-pixels and include a first light-emitting region and a second light-emitting region, wherein the first light-emitting region is configured to emit light with a first color and in a first wavelength range, and the second light-emitting region is configured to emit light with a second color and in a second wavelength range; an optical adjustment layer, disposed on a light exiting side of the light-emitting device layer, wherein the optical adjustment layer is configured to have a transmittance for light in the first wavelength range being smaller than a transmittance thereof for light in the second wavelength range, and to have a reflectivity for light in the first wavelength range being greater than a reflectivity thereof for light in the second wavelength range, wherein the optical adjustment layer at least covers the first light-emitting region, and an orthographic projection of the first light-emitting region on the base substrate is located within an orthographic projection of the optical adjustment layer on the base substrate; and an antireflection layer, disposed on a side of the optical adjustment layer away from the light-emitting device layer.

In the display panel provided by at least one embodiment of the present disclosure, a wavelength of the first wavelength range is smaller than a wavelength of the second wavelength range.

In the display panel provided by at least one embodiment of the present disclosure, the optical adjustment layer has a transmittance in a range of 30% to 70% for light in the first wavelength range, and has a reflectivity in a range of 30% to 70% for light in the first wavelength range.

In the display panel provided by at least one embodiment of the present disclosure, the plurality of light-emitting regions further include a third light-emitting region configured to emit light with a third color and in a third wavelength range, and the optical adjustment layer is configured to have a transmittance for light in the third wavelength range being greater than a transmittance thereof for light in the first wavelength range, and to have a reflectivity for light in the third wavelength range being smaller than a reflectivity thereof for light in the first wavelength range.

In the display panel provided by at least one embodiment of the present disclosure, the optical adjustment layer has a transmittance greater than 80% and a reflectivity smaller than 15% for at least part of light in the second wavelength range and the third wavelength range.

In the display panel provided by at least one embodiment of the present disclosure, the first wavelength range is 440 nm to 500 nm, one of the second wavelength range and the third wavelength range is 500 nm to 580 nm, and the other one of the second wavelength range and the third wavelength range is 580 nm to 650 nm, and the first color is blue color, one of the second color and the third color is green color, and the other one of the second color and the third color is red color.

In the display panel provided by at least one embodiment of the present disclosure, the plurality of sub-pixels include a red sub-pixel, a green sub-pixel and a blue sub-pixel, and the first light-emitting region, the second light-emitting region and the third light-emitting region are light-emitting regions of the blue sub-pixel, the green sub-pixel and the red sub-pixel respectively; and an aperture ratio of the blue sub-pixel is greater than or equal to an aperture ratio of the red sub-pixel, an aperture ratio of the green sub-pixel is greater than or equal to an aperture ratio of the red sub-pixel, the aperture ratio of the red sub-pixel is smaller than or equal to 8%, and a maximum aperture ratio of the blue sub-pixel and the green sub-pixel is smaller than or equal to 10%.

In the display panel provided by at least one embodiment of the present disclosure, the optical adjustment layer is configured such that a color deviation value CIEx or CIEy of light obtained after incident light emitted from the plurality of light-emitting regions passing through the optical adjustment layer with relative to the incident light is smaller than or equal to 0.005.

In the display panel provided by at least one embodiment of the present disclosure, the first light-emitting region, the second light-emitting region and the third light-emitting region are light-emitting regions of a blue sub-pixel, a green sub-pixel and a red sub-pixel respectively, and the optical adjustment layer is configured such that a color deviation value CIEx or CIEy of exiting light obtained after first incident light emitted from the first light-emitting region passing through the optical adjustment layer with relative to the first incident light is smaller than or equal to 0.001; a color deviation value CIEx or CIEy of exiting light obtained after second incident light emitted from the second light-emitting region passing through the optical adjustment layer with relative to the second incident light is smaller than or equal to 0.002; and a color deviation value CIEx or CIEy of exiting light obtained after third incident light emitted from the third light-emitting region passing through the optical adjustment layer with relative to the third incident light is smaller than or equal to 0.003.

In the display panel provided by at least one embodiment of the present disclosure, the optical adjustment layer is a continuous film layer, and orthographic projections of the second light-emitting region and the third light-emitting region on the base substrate both are also located within the orthographic projection of the optical adjustment layer on the base substrate.

In the display panel provided by at least one embodiment of the present disclosure, orthographic projections of the first light-emitting region, the second light-emitting region and the third light-emitting region on the base substrate are located within an orthographic projection of the antireflection layer on the base substrate.

In the display panel provided by at least one embodiment of the present disclosure, the optical adjustment layer is configured to transmit a first part of light among light emitted from the first light-emitting region and reflect a second part of light among the light emitted from the first light-emitting region, and the antireflection layer is configured to transmit the first part of light.

In the display panel provided by at least one embodiment of the present disclosure, the optical adjustment layer is further configured to reflect the second part of light to at least one film layer located between the optical adjustment layer and the base substrate, and the second part of light is further reflected by the at least one film layer and emitted to the optical adjustment layer as first sub-light; the optical adjustment layer is configured to transmit at least part of the first sub-light; and the antireflection layer is configured to transmit the at least part of the first sub-light.

In the display panel provided by at least one embodiment of the present disclosure, the light-emitting device layer includes a reflective electrode, and the at least one film layer that reflects the second part of light includes the reflective electrode.

In the display panel provided by at least one embodiment of the present disclosure, the first part of light has a first polarization state, the second part of light has a second polarization state, and a polarization state of the second part of light is changed after being reflected by the at least one film layer, so that the first sub-light has the first polarization state.

In the display panel provided by at least one embodiment of the present disclosure, the antireflection layer at least includes a polarization conversion layer and a polarizing layer, the polarizing layer is located at a side of the polarization conversion layer away from the optical adjustment layer, and light with the first polarization state, after transmitting through the polarization conversion layer, have a polarization direction parallel to a polarization direction of the polarizing layer.

In the display panel provided by at least one embodiment of the present disclosure, further including a light-absorbing layer, and the light-absorbing layer is located at a side of the polarizing layer away from the polarization conversion layer.

In the display panel provided by at least one embodiment of the present disclosure, the orthographic projection of the optical adjustment layer on the base substrate is located within a range of an orthographic projection of the antireflection layer on the base substrate.

In the display panel provided by at least one embodiment of the present disclosure, further including: a spacer layer, defining a plurality of sub-pixel openings, wherein the plurality of light-emitting regions are respectively located in corresponding sub-pixel openings; and a light-shielding layer, located between the spacer layer and the optical adjustment layer in a direction perpendicular to a main surface of the base substrate, wherein the light-shielding layer has a plurality of light-transmitting openings, the plurality of sub-pixel openings are in one-to-one correspondence with the plurality of light-transmitting openings, and an orthographic projection of each of the plurality of sub-pixel openings on the base substrate is located within a range of an orthographic projection of a corresponding one of the plurality of light-transmitting openings on the base substrate.

In the display panel provided by at least one embodiment of the present disclosure, the spacer layer has a first sub-pixel opening corresponding to the first light-emitting region and a second sub-pixel opening corresponding to the second light-emitting region, and the light-shielding layer has a first light-transmitting opening corresponding to the first light-emitting region, and a second light-transmitting opening corresponding to the second light-emitting region; the spacer layer has a first spacer edge defining the first sub-pixel opening and a second spacer edge defining the second sub-pixel opening, and the light-shielding layer has a first light-shielding edge defining the first light-transmitting opening and a second light-shielding edge defining the second light-transmitting opening; and the first spacer edge and the first light-shielding edge have a first offset distance in a direction parallel to the main surface of the base substrate, and the second spacer edge and the second light-shielding edge have a second offset distance in the direction parallel to the main surface of the base substrate.

In the display panel provided by at least one embodiment of the present disclosure, the first offset distance is different from the second offset distance.

In the display panel provided by at least one embodiment of the present disclosure, the first offset distance is greater than the second offset distance.

In the display panel provided by at least one embodiment of the present disclosure, the first offset distance and the second offset distance are each smaller than or equal to 4 microns.

In the display panel provided by at least one embodiment of the present disclosure, first exiting light and second exiting light that are respectively obtained after light emitted from the first light-emitting region and the second light-emitting region passing through the optical adjustment layer and the antireflection layer have a first luminance attenuation value and a second luminance attenuation value at a nonzero-degree viewing angle, respectively, wherein the first luminance attenuation value is a percentage of a difference between a luminance of the first exiting light at the nonzero-degree viewing angle and an initial luminance of the first exiting light at a zero-degree viewing angle to the initial luminance, the second luminance attenuation value is a percentage of a difference between a luminance of the second exiting light at the nonzero-degree viewing angle and an initial luminance of the second exiting light at a zero-degree viewing angle to the initial luminance; and at a same viewing angle, the first luminance attenuation value is greater than the second luminance attenuation value.

In the display panel provided by at least one embodiment of the present disclosure, the first luminance attenuation value ranges from 32% to 40% and the second luminance attenuation value ranges from 17% to 28%, at a viewing angle of 30 degrees; the first luminance attenuation value ranges from 62% to 70% and the second luminance attenuation value ranges from 55% to 57.5% at a viewing angle of 45 degrees.

In the display panel provided by at least one embodiment of the present disclosure, a difference between the first luminance attenuation value and the second luminance attenuation value at the same viewing angle is equal to or less than 7.5%.

In the display panel provided by at least one embodiment of the present disclosure, the spacer layer includes a light-absorbing material, an optical density of the spacer layer is not smaller than 0.5/m, and a slope angle of the spacer layer is smaller than or equal to 35 degrees.

In the display panel provided by at least one embodiment of the present disclosure, the light-shielding layer includes a light-absorbing material, and an optical density of the light-shielding layer is not smaller than 0.5/m.

In the display panel provided by at least one embodiment of the present disclosure, the spacer layer is free of a light-absorbing material.

In the display panel provided by at least one embodiment of the present disclosure, the spacer layer includes a light-absorbing material, and the light-absorbing material of the spacer layer is as same as the light-absorbing material of the light-shielding layer.

In the display panel provided by at least one embodiment of the present disclosure, a slope angle of the light-shielding layer is greater than or equal to a slope angle of the spacer layer.

In the display panel provided by at least one embodiment of the present disclosure, the light-emitting device layer includes a first light-emitting layer and a second light-emitting layer, the first light-emitting layer includes at least a part located in the first light-emitting region, and the second light-emitting layer includes at least a part located in the second light-emitting region; a thickness of the first light-emitting layer in a direction perpendicular to a main surface of the base substrate ranges from 15 nm to 25 nm; and a thickness of the second light-emitting layer in the direction perpendicular to the main surface of the base substrate ranges from 25 nm to 40 nm.

In the display panel provided by at least one embodiment of the present disclosure, further including an encapsulation layer located at a side of the light-emitting device layer close to the optical adjustment layer, wherein the encapsulation layer has a multi-layer structure, and a refractive index of at least two layers of the multi-layer structure is greater than or equal to 1.65.

In the display panel provided by at least one embodiment of the present disclosure, the encapsulation layer at least includes an inorganic structure layer and an organic structure layer, and a coverage area of the inorganic structure layer is greater than or equal to a coverage area of the organic structure layer.

In the display panel provided by at least one embodiment of the present disclosure, further including a light extraction layer located between the light-emitting device layer and the encapsulation layer, and a difference between a refractive index of the light extraction layer and a refractive index of a material layer in the encapsulation layer that is in contact with the light extraction layer is equal to or greater than 0.1.

At least one embodiment of the present disclosure provides a display device, including any one of the above-mentioned display panels.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1 illustrates a schematic cross-sectional view of a display substrate according to some embodiments of the present disclosure.

FIG. 2A schematically illustrates a light path diagram of light emitted from a light-emitting region of a display panel according to some embodiments of the present disclosure; FIG. 2B schematically illustrates a light extraction principle of light emitted from a light-emitting region in a display panel according to some embodiments of the present disclosure.

FIG. 3 illustrates a schematic cross-sectional view of a display substrate according to some embodiments of the present disclosure.

FIG. 4 illustrates a schematic plan view of an arrangement of sub-pixels in a pixel unit of a display panel according to some embodiments of the present disclosure.

FIG. 5A is a diagram of curve illustrating transmittance of an optical adjustment layer, for light in various wavelength ranges, of a display panel according to some embodiments of the present disclosure; FIG. 5B is a diagram of curve illustrating reflectivity of an optical adjustment layer, for light in various wavelength ranges, of a display panel according to some embodiments of the present disclosure.

FIG. 6 is a diagram of curves schematically illustrating overall reflectivity of display panels according to some embodiments of the present disclosure.

FIG. 7A to FIG. 7C schematically illustrates diagrams of L-Decay curves of viewing angle luminance attenuations, under various viewing angles, of a display panel according to some embodiments of the present disclosure.

FIG. 8 is a diagram of curves schematically illustrating a device performance of a display panel varied with changes of a transmittance of an optical adjustment layer, according to some embodiments of the present disclosure.

FIG. 9 illustrates a schematic cross-sectional view of a display panel according to some embodiments of the present disclosure.

FIG. 10A to FIG. 10C are schematic cross-sectional views illustrating a more specific structure of a partial region of FIG. 9 in some other embodiments.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., used in the present disclosure are not intended to indicate any sequence, amount or importance, but distinguish different components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not limited to a physical connection or mechanical connection, but may also include an electrical connection, directly or indirectly.

An embodiment of the present disclosure provides a display panel, which includes a plurality of sub-pixels arranged in an array, and includes a base substrate, a light-emitting device layer, an optical adjustment layer and an antireflection layer. The light-emitting device layer is disposed on a side of the base substrate and includes a plurality of light-emitting regions configured to emit light of different colors, the plurality of light-emitting regions respectively correspond to the plurality of sub-pixels and include a first light-emitting region and a second light-emitting region, wherein the first light-emitting region is configured to emit light of a first color in a first wavelength range, and the second light-emitting region is configured to emit light of a second color in a second wavelength range; the optical adjustment layer is disposed on a light exiting side of the light-emitting device layer, and is configured to have a transmittance for light in the first wavelength range being smaller than a transmittance for light in the second wavelength range, and have a reflectivity for light in the first wavelength range being greater than a reflectivity for light in the second wavelength range, wherein the optical adjustment layer covers at least the first light-emitting region, and an orthographic projection of the first light-emitting region on the base substrate is located within an orthographic projection of the optical adjustment layer on the base substrate; and the antireflection layer is disposed on a side of the optical adjustment layer away from the light-emitting device layer.

In the embodiment of the present disclosure, by providing the optical adjustment layer and the antireflection layer and configuring the transmittance and reflectivity of the optical adjustment layer to have the above-described characteristics, the optical adjustment layer is capable of improving the light extraction efficiency of the first light-emitting region and enhancing the luminous brightness of the display panel corresponding to the first light-emitting region; meanwhile, disposing the optical adjustment layer substantially has little or no influence on the light extraction efficiency and luminous brightness of the second light-emitting region. In some embodiments, the first light-emitting region is, for example, a blue light-emitting region, and the second light-emitting region is, for example, a green light-emitting region or a red light-emitting region or a light-emitting region with another color. That is to say, in some embodiments, through providing the optical adjustment layer and the antireflection layer, the light extraction efficiency and luminous brightness of the blue light-emitting region of the display panel can be increased; moreover, since other light-emitting regions such as red and green light-emitting regions already have good light extraction efficiency and luminous brightness, the light extraction efficiency and luminous brightness of these regions are substantially not affected by the optical adjustment layer, so that the light extraction efficiency and luminous brightness of blue light are close to those of red, green or other light, the difference between luminance of blue light and luminance of red and green light is reduced, and the display quality of the display panel is further improved.

On the other hand, since disposing the optical adjustment layer and the antireflection layer can enhance the light extraction efficiency and luminous brightness of blue light, even if the blue sub-pixel has relatively small light-emitting area, the current density of the blue sub-pixel can be adjusted to be relatively low, thus ensuring the lifespan of blue light; that is, both the lifespan and luminance of blue light can be guaranteed without loss at the same time. Therefore, in some embodiments, through providing the optical adjustment layer and the antireflection layer, the aperture ratio of blue sub-pixel can be optimized on the premise of ensuring the lifespan and luminous brightness of blue light, thereby optimizing the overall aperture ratio of pixels in the display panel, and the area of a single sub-pixel (e.g., a blue sub-pixel) can be reduced, and the number of pixels in a unit area can be increased, thereby realizing high display pixel density (e.g., pixels per inch, PPI); moreover, the power consumption of the display panel can also be reduced. In addition, the interval between different light-emitting regions can be set in a suitable range, which reduces the process difficulty and improves the yield of the display panel.

FIG. 1 illustrates a schematic cross-sectional view of a display substrate according to some embodiments of the present disclosure.

Referring to FIG. 1, in some embodiments, a display substrate 50 includes a plurality of sub-pixels arranged in an array, and includes a base substrate 10, a light-emitting device layer LE, an optical adjustment layer 20, and an antireflection layer 22. The light-emitting device layer LE is located on a side of the base substrate 10 and includes a plurality of light-emitting regions; the plurality of light-emitting regions respectively correspond to the plurality of sub-pixels. The optical adjustment layer 20 and the antireflection layer 22 are disposed on a light exiting side of the light-emitting device layer LE, and the optical adjustment layer 20 is located between the light-emitting device layer LE and the antireflection layer 22. The plurality of light-emitting regions are configured to emit light of different colors. For example, the plurality of light-emitting regions include light-emitting regions R1, R2, R3; the light-emitting region R1 may also be referred to as a first light-emitting region, and the light-emitting regions R2 and R3 may be referred to as a second light-emitting region and a third light-emitting region respectively, or vice versa. The following description refers to the case where the light-emitting region R2 is the second light-emitting region and the light-emitting region R3 is the third light-emitting region by way of example. In some embodiments, the first light-emitting region R1 is configured to emit light in a first wavelength range and having a first color, the second light-emitting region R2 is configured to emit light in a second wavelength range and having a second color, and the third light-emitting region R3 is configured to emit light in a third wavelength range and having a third color.

In some embodiments, a wavelength in the first wavelength range is smaller than wavelengths in the second wavelength range and the third wavelength range. In some embodiments, the first wavelength range is a blue light wavelength range, one of the second wavelength range and the third wavelength range is a green light wavelength range, and the other one of the second wavelength range and the third wavelength range is a red light wavelength range. For example, the color of light emitted from the light-emitting region R1 is blue color, and the range of blue light wavelength range is about 440 nm to 500 nm; the color of light emitted from the light-emitting region R2 is green color, and the range of green light wavelength range is about 500 nm to 580 nm; the color of light emitted from the light-emitting region R3 is red color, and the range of red light wavelength range is about 580 nm to 650 nm. For example, the light-emitting regions R1, R2 and R3 are the light-emitting regions of the corresponding blue, green and red sub-pixels, respectively.

In some embodiments, the optical adjustment layer 20 is disposed on the light exiting side of the light-emitting device layer LE; the optical adjustment layer 20 is configured to have a transmittance for light in a first wavelength range (e.g., blue light wavelength range) being smaller than a transmittance for light in a second wavelength range (e.g., green light wavelength range) and a transmittance for light in a third wavelength range (e.g., red light wavelength range), and to have a reflectivity for light in the first wavelength range being greater than a reflectivity for light in the second wavelength range and a reflectivity for light in the third wavelength range. For example, the optical adjustment layer 20 has a transmittance of about 30% to 70% and a reflectivity of about 30% to 70% for light in the first wavelength range. In some examples, the transmittance and reflectivity of the optical adjustment layer 20 for light in the first wavelength range are both 50%, that is, the optical adjustment layer 20 may be semi-transmissive and semi-reflective for light in the first wavelength range. For example, the optical adjustment layer 20 has a transmittance of greater than 80% and a reflectivity of smaller than 15% for at least part of light in the second wavelength range and the third wavelength range.

In some embodiments, the optical adjustment layer 20 has a transmittance greater than 80% and a reflectivity smaller than 15% for light in at least half of wavelength range region of the visible light wavelength range (380-780 nm). The at least half of wavelength range region may include at least part of the red light wavelength range and at least part of the green light wavelength range, but does not include the blue light wavelength range. The optical adjustment layer 20 may have a transmittance and a reflectivity both ranging from 30% to 70% at least in a specific wavelength range where the difference between a maximum wavelength and a minimum wavelength is 30±20 nm; the specific wavelength range at least covers at least part of the blue light wavelength range, for example, the specific wavelength range may completely or partially overlap with the blue light wavelength range.

In some embodiments, the optical adjustment layer 20 covers at least the light-emitting region R1, and may further cover the light-emitting regions R2 and R3; in other words, the orthographic projection of the light-emitting region R1 on the base substrate 10 is located within the range of orthographic projection of the optical adjustment layer 20 on the base substrate 10; the orthographic projections of the light-emitting regions R2 and R3 on the base substrate may overlap (e.g., partly overlap or completely overlap) or may not overlap with the orthographic projection of the optical adjustment layer 20 on the base substrate 10. In some embodiments, the optical adjustment layer 20 is a continuous film layer extending continuously on the light exiting sides of the light-emitting regions R1 to R3, and the orthographic projections of the light-emitting regions R1, R2 and R3 on the base substrate 10 are all located within the range of orthographic projection of the optical adjustment layer 20 on the base substrate 10. Herein, the orthographic projection of a component on the base substrate 10 refers to the projection of the component on the base substrate 10 in a direction perpendicular to the main surface of the base substrate 10.

In some embodiments, the antireflection layer 22 is disposed on a side of the optical adjustment layer 20 away from the light-emitting device layer LE, that is, on the light exiting side of the optical adjustment layer 20. The antireflection layer 22 covers a plurality of light-emitting regions, for example, the orthographic projections of the light-emitting regions R1-R3 on the base substrate 10 are all located within the range of orthographic projection of the antireflection layer 22 on the base substrate 10. In some embodiments, the antireflection layer 22 is configured to avoid or reduce the situation that the ambient light incident on the display panel is reflected by the film layers in the display panel and then exits from the display panel, thereby reducing the reflectivity of the display panel and improving the contrast of the display panel. In some embodiments, the antireflection layer 22 may transmit at least part of the light of the plurality of light-emitting regions. For example, the antireflection layer 22 has a transmittance of 40% or more (e.g., 50%) for light in the wavelength range ranging from 460 nm to 630 nm. That is, in some embodiments, the antireflection layer 22 also has a certain blocking effect on the light emitted by the light-emitting regions R1-R3.

In some embodiments, the coverage area of the optical adjustment layer 20 is not greater than that of the antireflection layer 22; for example, the orthographic projection of the optical adjustment layer 20 on the base substrate 10 is located within the range of orthographic projection of the antireflection layer 22 on the base substrate 10. In some embodiments, by providing the optical adjustment layer 20 and the antireflection layer 22 described above, the light extraction efficiency and luminous brightness of the light-emitting region R1 (e.g., the blue light region) can be increased, without substantially affecting the light emission of the light-emitting regions R2 and R3.

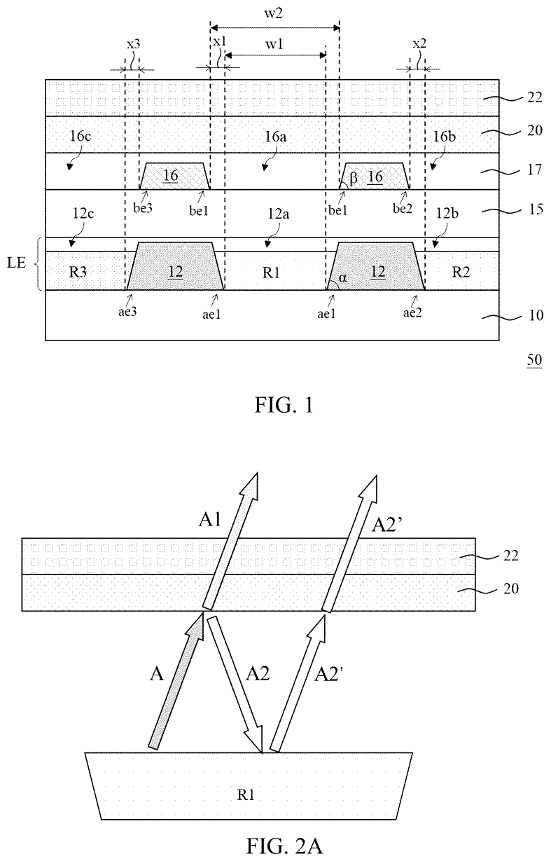

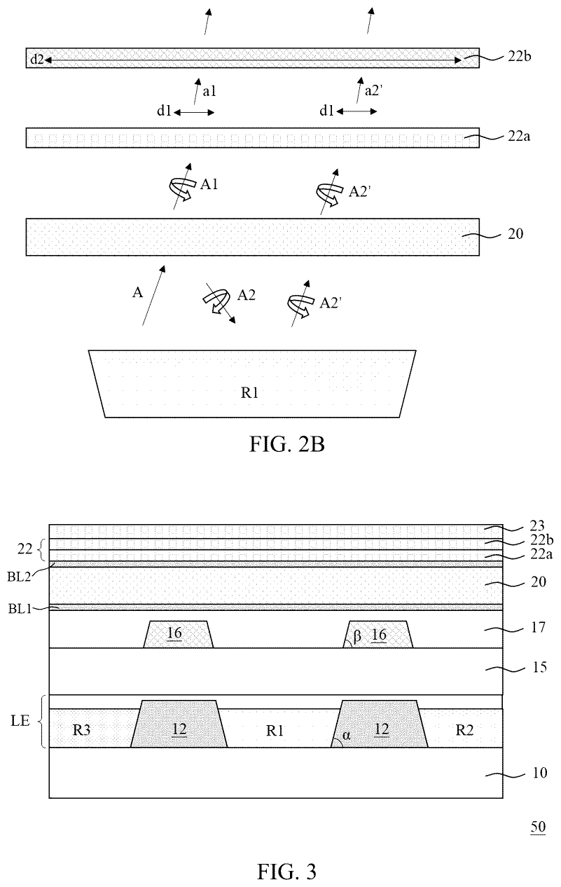

FIG. 2A schematically illustrates a light path diagram of light emitted from the light-emitting region R1. FIG. 2B schematically illustrates the light exiting principle of the light emitted by the light-emitting region R1.

For example, referring to FIGS. 1 and 2A, in some embodiments, the optical adjustment layer 20 is configured to transmit a first part of light A1 in light A emitted from the light-emitting region R1 and reflect a second part of light A2 in the light A, and the antireflection layer 22 is configured to transmit the first part of light A1. For example, after transmitting through the optical adjustment layer 20, the first part of light A1 can be at least mostly (e.g., completely) transmitted through the antireflection layer 22, and then exits from the light exiting surface of the display panel. In some embodiments, the second part of light A2 reflected by the optical adjustment layer 20 is incident onto at least one film layer between the optical adjustment layer 20 and the base substrate 10, and is further reflected by the at least one film layer and emitted toward the optical adjustment layer 20, again, as a first sub-light A2′. At least part (e.g., all) of the first sub-light A2′ is transmitted through the optical adjustment layer 20, and can be further transmitted through the antireflection layer 22, and then exits from the light exiting surface of the display panel. For example, after being reflected, the second part of light A2 can be at least mostly (e.g., completely) transmitted through the optical adjustment layer 20 and the antireflection layer 22. Since the optical adjustment layer 20 reflects the second part of light A2, and the second part of light A2 is reflected by the at least one film layer and then exits after passing through the optical adjustment layer 20 and the antireflection layer 22, the light extraction efficiency and luminous brightness of the light-emitting region R1 are improved.

Referring to FIG. 2A and FIG. 2B, in some embodiments, the antireflection layer 22 includes a polarization conversion layer 22a and a polarizing layer 22b; the polarization conversion layer 22a and the polarizing layer 22b are sequentially arranged in the light exiting direction of the optical adjustment layer 20. For example, the polarization conversion layer 22a is disposed on the side of the optical adjustment layer 20 away from the light-emitting region, and the polarizing layer 22b is disposed on the light exiting side of the polarization conversion layer 22a, for example, the side of the polarization conversion layer 22a away from the optical adjustment layer 20.

For example, the polarization conversion layer 22a may be a phase retardation film with phase retardation which is an integer multiple of ¼λ, and has non-positive wavelength dispersion. The polarization conversion layer 22a may convert circularly polarized light into linearly polarized light, or may convert linearly polarized light into circularly polarized light. The polarizing layer 22b is configured to have a polarization direction d2 and can transmit light with a polarization direction parallel to the polarization direction of the polarizing layer 22b. In some embodiments, the polarizing layer 22b is configured to have a transmittance of not smaller than 40%, for example, about 50% for the light in the wavelength range of 460-630 nm.

FIG. 2B schematically illustrates the light exiting principle of the light exited after being emitted from the light-emitting region R1 and passed through the optical adjustment layer 20 as well as the polarization conversion layer 22a and the polarizing layer 22b of the antireflection layer 22. In order to clearly illustrate the state of the light after passing through the respective layers, the optical adjustment layer 20, the polarization conversion layer 22a and the polarizing layer 22b are shown as separate in the figure, but it should be understood that two adjacent layers of these layers may be immediately adjacent to each other or in contact with each other.

Referring to FIG. 2B, in some embodiments, in the light A emitted by the light-emitting region R1, the first part of light A1 has a first polarization state and the second part of light A2 has a second polarization state. The optical adjustment layer 20 is configured to transmit light having a first polarization state and reflect light having a second polarization state; and the light with the first polarization state, after passing through the polarization conversion layer 22a of the antireflection layer 22, has a polarization direction parallel to the polarization direction of the polarizing layer 22b, and thus can be transmitted through the antireflection layer 22.

For example, the first polarization state and the second polarization state may be circular polarization states in different directions (e.g., opposite directions), for example, the first part of light A1 is left-handed circularly polarized light, the second part of light is right-handed circularly polarized light, or vice versa. Light with the first polarization state (e.g., left-handed circularly polarized light), after being transmitted through the optical adjustment layer 20, passes through the polarization conversion layer 22a and is converted into linearly polarized light by the polarization conversion layer 22a; and the polarization direction of the linearly polarized light is parallel to the polarization direction of the polarizing layer 22b, so that the linearly polarized light can be transmitted through the polarizing layer 22b and exits.

In some embodiments, light with the second polarization state (e.g., right-handed circularly polarized light) is reflected, by the optical adjustment layer 20, to at least one film layer (e.g., a reflective electrode of the light-emitting device layer, etc.) located between the optical adjustment layer 20 and the base substrate 10, and the light with the second polarization state can be at least partially further reflected by the at least one film layer and emitted, again, to the optical adjustment layer 20. In some embodiments, the light with the second polarization state (e.g., right-handed circularly polarized light) is changed (e.g., reversed) in its polarization state after being reflected by the at least one film layer, and converted into light with the first polarization state (e.g., left-handed circularly polarized light), so that it can pass through the optical adjustment layer 20 and the antireflection layer 22 including the polarization conversion layer 22a and the polarizing layer 22b.

That is to say, for the light A emitted from the light-emitting region R1, the optical adjustment layer 20 transmits a first part of light A1 (e.g., left-handed circularly polarized light) and reflects a second part of light A2 (e.g., right-handed circularly polarized light); then, the first part of light A1 is transmitted through the polarization conversion layer 22a and converted into light a1, which, for example, is linearly polarized light with polarization direction d1, and the polarization direction d1 of the linearly polarized light a1 is parallel to the polarization direction d2 of the polarizing layer 22b, so that the linearly polarized light a1 can be transmitted through the polarizing layer 22b and exit. The second part of light A2 (e.g., right-handed circularly polarized light) reflected by the optical adjustment layer 20 is incident onto at least one film layer located between the optical adjustment layer 20 and the base substrate, and further reflected by the at least one film layer (which may, for example, include a reflective electrode of the light-emitting device layer) and is emitted, again, to the optical adjustment layer 20 as a first sub-light A2′. After being reflected by the at least one film layer, the polarization state of the second part of light A2 changes, for example, from right-handed circularly polarized light to left-handed circularly polarized light, that is, the first sub-light A2 is left-handed circularly polarized light, and thus can be transmitted through the optical adjustment layer 20; and then the first sub-light A2 is transmitted through the polarization conversion layer 22a and converted into light a2′, which is, for example, linearly polarized light with polarization direction d1, and the polarization direction d1 of the linearly polarized light a2′ is parallel to the polarization direction d2 of the polarizing layer 22b, so that the linearly polarized light a2′ can be transmitted through the polarizing layer 22b and exit.

In a conventional display panel without an optical adjustment layer, the polarization direction of part of the light emitted by the light-emitting region R1, after being transmitted through the polarization conversion layer, is different from (e.g., perpendicular to) the polarization direction of the polarizing layer, and thus the part of light cannot be transmitted through the polarizing layer in the antireflection layer. While in this embodiment, an optical adjustment layer is provided between the light-emitting device layer and the antireflection layer, and the optical adjustment layer is configured to transmit light with a first polarization state and reflect light with a second polarization state, that is, such that the second part of the light emitted from the light-emitting region R1 is reflected by the optical adjustment layer, for example, reflected to a film layer such as a reflective electrode, and then further reflected by the film layer, and the polarization state thereof is converted, through which this second part of the light can also be transmitted through the optical adjustment layer and the antireflection layer and exit, thereby improving the light extraction efficiency and luminous brightness of the light-emitting region R1. It should be understood that, the polarization state and polarization direction of the respective light shown in FIG. 2B are only for illustration, and the present disclosure is not limited thereto.

The principle that the optical adjustment layer described above with reference to FIG. 2B realizes partial transmission and partial reflection of light in the light-emitting region R1 by selecting polarization state is only an example, and the present disclosure is not limited thereto. In some other embodiments, the optical adjustment layer may also be other types of partially transmissive and partially reflective films (e.g., a semi-transmissive and semi-reflective film) for the light in the light-emitting region R1.

On the other hand, in some embodiments, an optical microcavity is formed between the optical adjustment layer 20 and a film layer such as the reflective electrode of the light-emitting device layer. A part of the light emitted from the light-emitting region R1, after being reflected by the optical adjustment layer 20, may be subjected to multiple times of reflection (also referred to as optical oscillation) in the optical microcavity and then transmitted through the optical adjustment layer and the antireflection layer. Such optical oscillation can also enhance the intensity of this part of light, thereby enhancing the overall luminous brightness of this light-emitting region.

In some embodiments, the optical adjustment layer 20 is further configured such that the color deviation value CIEx or CIEy of the exiting light obtained after the incident light emitted from the light-emitting region of the light-emitting device layer passing through the optical adjustment layer 20 with relative to the incident light is smaller than or equal to 0.005. For example, the light-emitting regions R1, R2, R3 may be light-emitting regions of blue sub-pixel, green sub-pixel and red sub-pixel, respectively, and the optical adjustment layer is configured such that the color deviation value CIEx or CIEy of the exiting light obtained after the incident light (that is, blue light) emitted from the light-emitting region R1 passing through the optical adjustment layer with relative to the incident light is smaller than or equal to 0.001; the color deviation value CIEx or CIEy of the exiting light obtained after the incident light (e.g., green light) emitted from the light-emitting region R2 passing through the optical adjustment layer 20 with relative to the incident light is smaller than or equal to 0.002; and the color deviation value CIEx or CIEy of the exiting light obtained after the incident light emitted from the light-emitting region R3 passing through the optical adjustment layer 20 with relative to the incident light is smaller than or equal to 0.003.

By configuring the optical adjustment layer 20 such that the color deviation values of the light emitted from the respective light-emitting regions after passing through the optical adjustment layer are within the above ranges, the light extraction efficiency and luminous brightness of the light-emitting region R1 can be enhanced, while minimizing the color deviation of the light emitted from the respective light-emitting regions after passing through the optical adjustment layer, thereby improving the display quality of the display panel.

Referring back to FIG. 1, in some embodiments, the display panel 50 further includes a spacer layer 12 and a light-shielding layer 16. The spacer layer 12 defines a plurality of sub-pixel openings 12a, 12b, 12c, and the plurality of light-emitting regions R1, R2, R3 are respectively located in regions corresponding to the sub-pixel openings 12a, 12b, 12c, for example, located in the sub-pixel openings 12a, 12b, 12c. The spacer layer 12 may also be referred to as a pixel defining layer (PDL). The light-shielding layer 16 is located between the spacer layer 12 and the optical adjustment layer 20 in the direction perpendicular to the main surface of the base substrate 10. The light-shielding layer 1 defines a plurality of light-transmitting openings 16a, 16b, 16c, and the plurality of light-transmitting openings 16a-16c may be in one-to-one correspondence with the plurality of sub-pixel openings 12a-12c. For example, the light-transmitting opening 16a corresponds to the sub-pixel opening 12a and corresponds to the light-emitting region R1; the light-transmitting opening 16b corresponds to the sub-pixel opening 12b and corresponds to the light-emitting region R2; the light-transmitting opening 16c corresponds to the sub-pixel opening 12c and corresponds to the light-emitting region R3. The orthographic projection of the light-shielding layer 16 on the base substrate 10 overlaps with the orthographic projection of the spacer layer 12 on the base substrate 10, for example, the orthographic projection of the light-shielding layer 16 on the base substrate 10 may be located within the range of the orthographic projection of the spacer layer 12 on the base substrate 10. The light-shielding layer 16 may be configured to shield ambient light and prevent the ambient light from entering the display panel; and at the same time, the light emitted by the light-emitting regions R1-R3 of the sub-pixels can be emitted through these light-transmitting openings 16a-16b.

In some embodiments, the spacer layer 12 may include a light-absorbing material with an optical density (OD) which may be greater than or equal to 0.5/μm, but the present disclosure is not limited thereto. The light-shielding layer 16 may include a light-absorbing material with an optical density which may be greater than or equal to 0.5/μm. For example, the light-shielding layer 16 may include a black matrix (BM) material. In some embodiments, in the case that the light-shielding layer 16 is provided, the spacer layer 12 may or may not include a light-absorbing material. In the embodiment where both the light-shielding layer 16 and the spacer layer 12 include a light-absorbing material, the light-shielding layer 16 and the spacer layer 12 may include the same type of materials or different types of materials, which is not limited in the present disclosure.

In some embodiments, the sub-pixel opening and the light-transmitting opening corresponding to each other may have different sizes (e.g., width, area, etc.), for example, the size of the light-transmitting opening is greater than that of the corresponding sub-pixel opening, and the orthographic projection of each sub-pixel opening on the base substrate 10 may be located within the range of orthographic projection of the corresponding light-transmitting opening on the base substrate 10, so that the light emitted from the light-emitting region in the sub-pixel opening can be effectively emitted through the light-transmitting opening without being blocked, thereby ensuring a good light extraction efficiency for each sub-pixel.

Taking the sub-pixel opening 12a and the light-transmitting opening 16a corresponding to the light-emitting region R1 as an example, the width w1 of the sub-pixel opening 12a is smaller than the width w2 of the light-transmitting opening 16a. Here, the widths w1 and w2 are the bottom widths (i.e., the widths at the side away from the light exiting side of the display panel) of the sub-pixel opening 12a and the light-transmitting opening 16a, respectively. In some embodiments, an edge portion of the spacer layer 12 that defines the sub-pixel opening has a slope angle α, and the slope angle α is not greater than 35 degrees, that is, α≤35°; in this way, each sub-pixel opening can have an inverted trapezoid shape or a similar shape, and the width of the sub-pixel opening gradually increases, in the light exiting direction of the display panel, as being approaching the light exiting surface of the display panel. In the case where the display panel 50 has a top-emission structure, by way of example, as shown in FIG. 1, the width of the sub-pixel opening 12a gradually increases along the light exiting direction of the display panel 50 (that is, the upward direction in the figure). That is to say, the top width of the sub-pixel opening 12a is greater than the bottom width thereof. In some embodiments, by configuring the spacer layer 12 to have a slope angle within this range, the size of the sub-pixel opening gradually increases along the light exiting direction, so that the light emitted from the light-emitting regions of the respective sub-pixels can be effectively exited through the sub-pixel openings, thereby improving the light extraction efficiency of the sub-pixels.

In some embodiments, an edge portion of the light-shielding layer 16 that defines the light-transmitting opening has a slope angle β, and the slope angle β of the light-shielding layer 16 is not smaller than the slope angle α of the spacer layer 12, that is, β≥α≥35⁰. In some embodiments, the slope angle R of the light-shielding layer 16 may be smaller than 90°, so that each light-transmitting opening has an inverted trapezoid shape or a similar shape, that is, the width of the light-transmitting opening gradually increases, in the light exiting direction of the display panel, as approaching the light exiting surface of the display panel. In the case where the display panel 50 has a top-emission structure, by way of example, as shown in FIG. 1, the width of the light-transmitting opening 16a gradually increases along the light exiting direction of the display panel 50. That is to say, the top width of the light-transmitting opening 16a is greater than the bottom width thereof. In some other embodiments, the slope angle R of the light-shielding layer 16 may also be substantially equal to 90°, that is, the sidewall of the light-shielding layer 16 may extend in a direction substantially perpendicular to the main surface of the base substrate 10, so that the light-transmitting opening 16a may have a substantially uniform width, that is, the top width of the light-transmitting opening 16a may be substantially equal to the bottom width thereof. In some embodiments, the difference between the top width and the bottom width of the light-transmitting opening 16a is smaller than the difference between the top width and the bottom width of the corresponding sub-pixel opening 12a. In still some other embodiments, the slope angle of the light-shielding layer 16 may be slightly greater than 90 degrees, which is not limited in the present disclosure. It should be understood that, the above description is provided by taking the sub-pixel opening 12a and the light-transmitting opening 16a as an example, and other sub-pixel openings 12b, 12c and corresponding light-transmitting openings 16b, 16c also have similar positional relationships, which will not be repeated here. The edge portions of the spacer layer for defining different sub-pixel openings may have the same or different slope angles; and different sub-pixel openings may have the same or different shapes and sizes, etc.; the edge portions of the light-shielding layer for defining different light-transmitting openings may have the same or different slope angles, and different light-transmitting openings may have the same or different shapes and sizes.

In some embodiments, by setting the slope angle R of the light-shielding layer 16 to be not smaller than the slope angle α of the spacer layer 12, the light-shielding layer 16 can effectively shield the ambient light, thereby reducing the reflectivity of the display panel and improving the display contrast.

In some embodiments, the spacer layer 12 includes edge portions (or may be referred to as spacer edges) ae1, ae2, ae3 that define sub-pixel openings 12a, 12b, 12c, respectively; the light-shielding layer 16 includes edge portions (or may be referred to as light-shielding edges) be1, be2, be3 that define light-transmitting openings 16a, 16b, 16c, respectively. In some embodiments, the edge portions ae1, ae2, ae3 of the spacer layer 12 may also be referred to as a first spacer edge, a second spacer edge, and a third spacer edge, respectively; the edge portions be1, be2 and be3 of the light-shielding layer 16 may also be referred to as a first light-shielding edge, a second light-shielding edge and a third light-shielding edge. When observed in a plan view, the edge portions of the spacer layer 12 and the light-shielding layer 16 that define the respective openings may be in a ring shape, and each opening is surrounded by a corresponding edge portion. Here, the ring shape is not limited to a circular ring shape, but may include a ring of any shape (e.g., rectangular ring shape, pentagonal ring shape, hexagonal ring shape, etc.). It should be understood that the sub-pixel openings 12b, 12c and the corresponding edge portions ae2, ae3 of the spacer layer 12, as well as the light-transmitting openings 16b, 16c and the corresponding edge portions be2, be3 of the light-shielding layer 16, that are corresponding to the light-emitting regions R2 and R3, are only partially shown in FIG. 1, and their relative positional relationships are similar to those of the corresponding components in the light-emitting region R1.

In some embodiments, the spacer edge and light-shielding edge corresponding to the same light-emitting region are offset from each other in the direction parallel to the main surface of the base substrate 10, and the light-shielding edge is offset toward the direction away from the light-emitting region, so that the size of the corresponding light-transmitting opening is greater than the size of the sub-pixel opening. For example, the spacer edge ae1 and the light-shielding edge be1 corresponding to the light-emitting region R1 have an offset distance X1 in a direction parallel to the main surface of the base substrate 10; the spacer edge ae2 and the light-shielding edge be2 corresponding to the light-emitting region R2 have an offset distance x2 in the direction parallel to the main surface of the base substrate 10; the spacer edge ae3 and the light-shielding edge be3 corresponding to the light-emitting region R3 have an offset distance x3 in the direction parallel to the main surface of the base substrate 10. In some embodiments, the offset distances x1, x2 and x3 are each not greater than 4 microns (μm), that is, x1, x2, x3≤4 μm. By setting the offset distances within this range, it can be ensure that the light-shielding layer has enough area, and can effectively block the ambient light while fully transmitting the light from the light-emitting regions, so that the reflectivity of the display panel is small and the display contrast is good. The offset distances x1, x2 and x3 may be the same as or different from each other. For example, the offset distance x1 corresponding to the light-emitting region R1 (e.g., the light-emitting region of the blue sub-pixel) may be greater than the offset distances x2 and x3 corresponding to the light-emitting regions R2 and R3 (e.g., the light-emitting regions of the green and red sub-pixels). In some embodiments, by setting the offset distance x1 to be greater than the offset distances x2 and x3, the color deviation of the display panel at different viewing angles can be reduced, and the specific content will be described in detail later in combination with embodiments.

Still referring to FIG. 1, in some embodiments, the display panel 50 further includes an encapsulation layer 15 and a planarization layer 17. The encapsulation layer 15 is disposed between the light-emitting device layer LE and the light-shielding layer 16, for example, disposed on a side of the light-emitting device layer LE away from the base substrate 10, but the present disclosure is not limited thereto. The encapsulation layer 15 may be a single-layer structure or a multi-layer structure. In some embodiments, the encapsulation layer 15 is a multi-layer structure, for example, may include at least three layers, and the refractive index of at least two layers thereof is equal to or greater than 1.65, so that the light extraction efficiency of the light-emitting region can be improved. In some embodiments, the encapsulation layer 15 may include an organic material, an inorganic material, or a combination thereof. For example, the encapsulation layer 15 may at least include one inorganic structure layer and one organic structure layer, and the coverage area of the organic structure layer is not greater than that of the inorganic structure layer. For example, the orthographic projection of the organic structure layer on the base substrate 10 is located within the orthographic projection of the inorganic structure layer on the base substrate 10. By setting the coverage area of the inorganic structure layer to be greater than that of the organic structure layer, it can facilitate to preventing water vapor from entering the light-emitting device layer LE of the display panel, which is helpful for protecting the plurality of sub-pixels and ensures the device performance and reliability of the display panel.

In some embodiments, the planarization layer 17 is disposed between the encapsulation layer 15 and the optical adjustment layer 20, and covers the sidewall of the light-shielding layer 16 and the surface thereof at the side away from the encapsulation layer 15. In other words, the light-shielding layer 16 is embedded in the planarization layer 17. In some embodiments, disposing the planarization layer 17 can provide a flat surface for the overlying optical adjustment layer 20, that is, the optical adjustment layer can be formed on the flat surface, which can improve the uniformity of film thickness of the optical adjustment layer 20, so that the optical adjustment layer 20 can have a substantially uniform thickness and a flat surface and hence have good optical characteristics, thereby further improving the light extraction efficiency and luminous brightness of the light-emitting region R1, without substantially affecting the light emission of other light-emitting regions.

FIG. 3 illustrates a schematic cross-sectional view of a more specific structure of a display panel according to some embodiments of the present disclosure.

Referring to FIG. 3, in some embodiments, the display panel 50 may further include a light-absorbing layer 23. For example, the light-absorbing layer 23 may be disposed on a side of the antireflection layer 22 away from the optical adjustment layer 20. For example, the polarization conversion layer 22a, the polarizing layer 22b, and the light-absorbing layer 23 are sequentially arranged in the light exiting direction of the optical adjustment layer 20. In some embodiments, the light-absorbing layer 23 is configured to absorb ambient light, such as ultraviolet light, so as to reduce the reflectivity of the display panel and improve the contrast of the display panel. For example, the absorption wavelength of the light-absorbing layer 23 may be set to be equal to or less than 450 nm, or equal to or less than 430 nm. The light-absorbing layer 23 substantially does not absorb the light emitted from the light-emitting regions R1-R3. It should be understood that, the position of the light-absorbing layer 23 shown in FIG. 3 is only for illustration, and the present disclosure is not limited thereto. The light-absorbing layer 23 may be disposed at any suitable position in the light exiting direction of the light-emitting device layer LE, as long as the light-absorbing layer 23 can effectively absorb the ambient light and achieve the effect of reducing the reflectivity of the display panel. For example, in some other embodiments, the light-absorbing layer 23 may be located between the encapsulation layer 15 and the optical adjustment layer 20; alternatively, the light-absorbing layer 23 may be located between the encapsulation layer 15 and the light-emitting device layer LE.

In some embodiments, in the direction perpendicular to the main surface of the base substrate 10, a bonding layer may be provided on at least one of the two opposite sides of the optical adjustment layer 20; the bonding layer is used for bonding the optical adjustment layer 20 with an adjacent layer, and may include, for example, a material such as an adhesive. For example, a bonding layer BL1 may be disposed between the optical adjustment layer 20 and the encapsulation layer 17, and the optical adjustment layer 20 and the encapsulation layer 17 are bonded (e.g., adhered) with each other through the bonding layer BL; a bonding layer BL2 may be disposed between the optical adjustment layer 20 and the antireflection layer 22, and the optical adjustment layer 20 and the antireflection layer 22 are bonded (e.g., adhered) with each other through the bonding layer BL2. It should be understood that, the bonding mode between the optical adjustment layer 20 and each of the encapsulation layer 17 and the antireflection layer 22 is not limited thereto, and any suitable bonding process can be used. For example, the bonding layer BL2 may be omitted, and the optical adjustment layer 20 and the antireflection layer 22 may be directly laminated together.

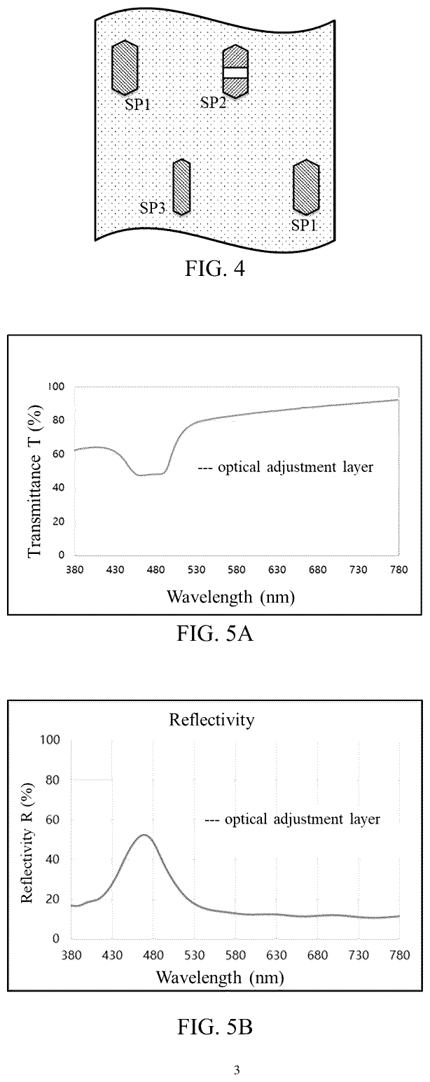

FIG. 4 illustrates a schematic plan view of an arrangement of sub-pixels in a pixel unit of a display panel according to some embodiments of the present disclosure.

Referring to FIG. 4, in some embodiments, the display panel includes a plurality of pixel units arranged in an array, and each pixel unit may include a plurality of sub-pixels, such as red sub-pixels, green sub-pixels and blue sub-pixels. FIG. 4 schematically illustrates a plurality of sub-pixels in one pixel unit. Referring to FIG. 1 and FIG. 4, in some embodiments, a plurality of light-emitting regions in the light-emitting device layer LE correspond to a plurality of sub-pixels, respectively; for example, the display panel includes sub-pixels SP1, SP2 and SP3, and the light-emitting regions R1, R2 and R3 in the light-emitting device layer LE are the light-emitting regions of sub-pixels SP1, SP2 and SP3, respectively. For example, the sub-pixels SP1, SP2 and SP3 are a blue sub-pixel, a green sub-pixel and a red sub-pixel, respectively. It should be understood that, the pixel arrangement shown in FIG. 4, the shapes and sizes of the respective sub-pixels and the like are only for illustration, and the present disclosure is not limited thereto.

In some embodiments, the aperture ratio of the blue sub-pixel is greater than or equal to the aperture ratio of the red sub-pixel, and the aperture ratio of the green sub-pixel is greater than or equal to the aperture ratio of the red sub-pixel; for example, the aperture ratio of the red sub-pixel is smaller than or equal to 8%, and the maximum aperture ratio of blue sub-pixel and green sub-pixel is smaller than or equal to 10%.

In order to better understand the influence of disposing the optical adjustment layer and the antireflection layer, as provided in the present disclosure, on the light emitted from various light-emitting regions, the present disclosure will be further elaborated in combination with embodiments and comparative examples, but it should be understood that the following examples are only illustrative, and the present disclosure is not limited thereto.

For example, each embodiment adopts the pixel structure shown in FIG. 4 and the structure of display panel shown in FIG. 1, and the light-emitting regions R1, R2 and R3 are the light-emitting regions of the blue sub-pixel SP1, the green sub-pixel SP2 and the red sub-pixel SP3 respectively, that is, the light-emitting regions R1, R2 and R3 are respectively configured to emit blue light, green light and red light. The luminescence characteristics of various Embodiments 1-5 in which the display panels are provided with optical adjustment layer and planarization layer are compared with the luminescence characteristics of Comparative Examples 1-2 in which the display panels are not provided with optical adjustment layer and planarization layer. In the Comparative Examples 1-2, the optical adjustment layer is not provided, the planarization layer is omitted, and the antireflection layer is formed on a side of encapsulation layer 15 away from the light-emitting device layer LE, and covers the light-shielding layer 16.

The related structural characteristics of the display panels and optical characteristics of the optical adjustment layers in the display panels of various Embodiments and Comparative Examples are shown in Table 1 as below:

TABLE 1

| | | | | Transmittance |
|---|---|---|---|---|
| | | | Whether optical | and reflectivity of |
| | Ratio of | Offset distance between | adjustment layer | optical adjustment layer |
| | aperture ratios | spacer edge and | and planarization | for respective wavelength |
| | of sub-pixels | light-shielding edge | layer are provided | ranges |
| Embodiment | SP3:SP1 = 1:1.8 | x1 = 4 μm; x2 = 4 μm | Yes | As shown in |
| 1 | SP3:SP2 = 1:1.2 | x3 = 4 μm | | FIG. 5A and FIG. 5B |
| Embodiment | SP3:SP1 = 1:1.8 | x1 = 2 μm; x2 = 2 μm | Yes | As shown in |
| 2 | SP3:SP2 = 1:1.2 | x3 = 2 μm | | FIG. 5A and FIG. 5B |
| Embodiment | SP3:SP1 = 1:1.8 | x1 = 4 μm; x2 = 4 μm | Yes | Transmittance of optical |
| 3 | SP3:SP2 = 1:1.2 | x3 = 4 μm | | adjustment layer for blue |
| | | | | light wavelength range is |
| | | | | adjusted |
| Embodiment | SP3:SP1 = 1:1.43 | x1 = 4 μm; x2 = 4 μm | Yes | As shown in |
| 4 | SP3:SP2 = 1:1.2 | x3 = 4 μm | | FIG. 5A and FIG. 5B |
| Embodiment | SP3:SP1 = 1:1.8 | x1 = 4 μm; x2 = 1.5 μm | Yes | As shown in |
| 5 | SP3:SP2 = 1:1.2 | x3 = 1.5 μm | | FIG. 5A and FIG. 5B |
| Comparative | SP3:SP1 = 1:1.8 | x1 = 4 μm; x2 = 4 μm | No | |
| example 1 | SP3:SP2 = 1:1.2 | x3 = 4 μm | | |
| Comparative | SP3:SP1 = 1:1.43 | x1 = 4 μm; x2 = 4 μm | No | |
| example 2 | SP3:SP2 = 1:1.2 | x3 = 4 μm | | |

In the above Embodiments 1, 2, 4 and 5, the transmittance and reflectivity of the optical adjustment layer 20 for the respective wavelength ranges are shown in FIGS. 5A and 5B. Referring to FIGS. 5A and 5B, the transmittance of the optical adjustment layer 20 for light in the wavelength range of about 440 nm to 500 nm (i.e., the blue light wavelength range) is smaller than the transmittance thereof for light in other wavelength ranges (e.g., the green light wavelength range of about 500 nm to 580 nm and the red light wavelength range of about 580 nm to 650 nm). For example, the optical adjustment layer 20 has a transmittance of about 50%, for example, about 47% to 52%, for light in the blue light wavelength range, and the optical adjustment layer 20 has a transmittance greater than 80% for at least part of light in the green light wavelength range and the red light wavelength range. Moreover, the reflectivity of the optical adjustment layer 20 for light in the blue light wavelength range is greater than the reflectivity thereof for light in other wavelength ranges (e.g., the green light wavelength range and the red light wavelength range). For example, the optical adjustment layer 20 has a reflectivity of about 30% to 57% for light in the blue light wavelength range, and the optical adjustment layer 20 has a reflectivity smaller than 20% or smaller than 15% for at least part of light in the green light wavelength range and the red light wavelength range.

The characteristics such as luminance, lifespan of sub-pixels and device power consumption of the respective light-emitting regions of the display panels in various Embodiments are tested and compared with those of the Comparative Examples. The testing results of Comparative Example 1, Embodiment 1, Embodiment 2 and Embodiment 5 are shown in Table 2 as below, and the related testing results of Comparative Example 1, Embodiment 1, Comparative Example 2 and Embodiment 4 are shown in Table 3 as below:

TABLE 2

| | R | | G | | B | | Device power |
|---|---|---|---|---|---|---|---|
| | L (%) | CIE (x, y) | L (%) | CIE (x, y) | L (%) | CIE (x, y) | consumption |
| Comparative | 100% | (0.682, 0.317) | 100% | (0.241, 0.722) | 100% | (0.139, 0.045) | 100% |
| example 1 | | | | | | | |
| Embodiment 1 | 103% | (0.681, 0.320) | 104% | (0.239, 0.723) | 127% | (0.139, 0.046) | 89.6% |
| Embodiment 2 | 102% | (0.681, 0.320) | 103% | (0.239, 0.723) | 126% | (0.139, 0.046) | 89.6% |
| Embodiment 5 | 102% | (0.681, 0.320) | 103% | (0.239, 0.723) | 126% | (0.139, 0.046) | 89.6% |

TABLE 3

| | R | | G | | B | | Device |
|---|---|---|---|---|---|---|---|
| | L (%) | Lifespan | L (%) | Lifespan | L (%) | Lifespan | power consumption |
| Comparative | 100% | 100% | 100% | 100% | 100% | 100% | 100% |
| example 1 | | | | | | | |
| Embodiment1 | 103% | 100% | 104% | 100% | 127% | 100% | 89.6% |
| Comparative | 100% | 99% | 100% | 98% | 120% | 84% | 100% |
| example 2 | | | | | | | |
| Embodiment4 | 102% | 99% | 102% | 99% | 133% | 100% | 89.5% |

In Table 2 and Table 3 listed above, R, G and B represent red (R) sub-pixel, green (G) sub-pixel and blue (B) sub-pixel of the display panel, respectively, L (%) represents the luminance of the corresponding sub-pixel, and CIE(x,y) represents the color coordinate value of the light emitted by the corresponding sub-pixel. It should be understood that, the luminance in Tables 2 and 3 refers to the luminance of the light exited from the light exiting surface of the display panel after the light emitted from the light-emitting region in the respective sub-pixel passing through the respective material layers at the light exiting side of the light-emitting region. In an example, the light-emitting regions R1, R2 and R3 in FIG. 1 correspond to the light-emitting regions of blue, green and red sub-pixels, respectively.

Referring to Table 1 to Table 3 listed above, the respective parameter settings are the same for Embodiment 1 and Comparative Example 1, with the difference that an optical adjustment layer and a planarization layer are provided in Embodiment 1, and the related optical characteristics of the optical adjustment layer are shown in FIGS. 5A and 5B. Comparing the testing results of Embodiment 1 and Comparative Example 1, it can be seen that, as compared with Comparative Example 1, after providing the optical adjustment layer in Embodiment 1, the luminance of blue light is improved by 27%, while the luminance of red light and the luminance of green light are substantially unchanged, for example, the luminance of red light and the luminance of green light are improved by a percentage equal to or smaller than 5%. Moreover, the color coordinates of the light emitted by the respective sub-pixels of the display panel (e.g., the blue light emitted by the blue (B) light-emitting region R1, the green light emitted by the green (G) light-emitting region, and the red light emitted by the red (R) light-emitting region) are substantially unchanged after passing through the optical adjustment layer; for example, the color deviation value CIEx or CIEy of the light in each light-emitting region after passing through the optical adjustment layer is equal to or less than 0.005. In addition, the overall device power consumption of the display panel is decreased by 10.4%. Therefore, by providing the optical adjustment layer, the luminance of blue light can be obviously improved, while the light in other wavelength ranges (e.g., green light and red light) is substantially not affected or less influenced; and at the same time, the optical adjustment layer substantially would not cause color cast of light in the respective wavelength ranges or has little influence thereon. That is to say, the optical adjustment layer can improve the luminance of blue light without basically causing any color cast and without substantially affecting the light in other wavelength ranges. Due to the luminance of blue light being enhanced, the overall device power consumption of the display panel can be reduced.

In addition, due to the arrangement of the optical adjustment layer, the Embodiments 2, 4, and 5 can also achieve the same effects as described above with respect to Embodiment 1.

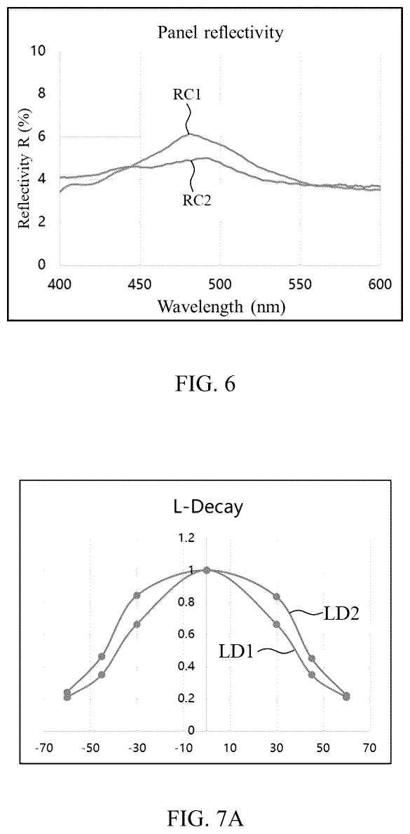

Comparing the embodiment 1 and the embodiment 2, as compared with Embodiment 1, the offset distances x1, x2 and x3 corresponding to the spacer edges and light-shielding edges of the respective light-emitting regions are set to be relatively smaller in Embodiment 2. FIG. 6 illustrates a reflectivity curve RC1 corresponding to the display panel in Embodiment 1 and a reflectivity curve RC2 corresponding to the display panel in Embodiment 2. It can be seen from FIG. 6 that, in a certain range, with the decrease of the offset distances x1, x2 and x3, the reflectivity of the display panel decreases. This is because the offset distances x1, x2 and x3 between corresponding spacer edges and light-shielding edges are set to be relatively smaller in Embodiment 2, that is, the light-shielding area of the light-shielding layer 16 is set to be relatively large, so that more light can be shielded, thereby reducing the reflectivity of the display panel and further improving the display contrast.

Embodiment 1, Embodiment 4, Comparative Example 1 and Comparative Example 2 are compared, in which Embodiment 1 and Comparative Example 1 have the same aperture ratios for sub-pixels, Embodiment 4 and Comparative Example 2 have the same aperture ratios for sub-pixels, and in Embodiment 4 and Comparative Example 2, the aperture ratio of blue sub-pixel is set to be relatively small, and a single blue sub-pixel has a relatively smaller light-emitting region. It can be seen from Table 1 in combination with Table 3 that, by comparing Comparative Example 1 with Comparative Example 2, the lifespan of blue sub-pixel is sharply reduced in the case that an optical adjustment layer is not provided; this is because the aperture ratio of the blue sub-pixel decreases, and the area of the blue light-emitting region (e.g., the area of the light-emitting region R1) decreases; under the condition that the power supply voltage (e.g., VDD-VSS) of a driving circuit of the sub-pixel is unchanged, the current density of the blue sub-pixel is increased, and the luminance of the blue sub-pixel is greatly improved under a high-level current density; that is, in the case that the aperture ratio of the blue sub-pixel decreases, the increase of current density of the blue sub-pixel improves the luminance of the blue sub-pixel. However, the increase of current density also results in accelerated decay of lifespan of the blue sub-pixel, leading to a decrease of the lifespan of the blue sub-pixel. It can be seen from Embodiment 1 combined with Embodiment 4 that, after the optical adjustment layer is provided, since the optical adjustment layer can improve the luminance of blue light, the current density of the blue sub-pixel in Embodiment 4 can be adjusted to be substantially the same as that of the blue sub-pixel in Embodiment 1, thereby ensuring the lifespan of the blue sub-pixel; meanwhile, the optical adjustment layer can improve the luminance of blue light and reduce the device power consumption. That is to say, even under the condition that the aperture ratio of the blue sub-pixel is set to be small and the blue sub-pixel has a relatively small light-emitting region, the device luminance can still be improved and the device power consumption can be reduced while guaranteeing the lifespan of the device by providing the optical adjustment layer. Therefore, in the case that the optical adjustment layer is provided, the aperture ratio of the blue sub-pixel can be set to be relatively small to reduce the area of the sub-pixel, so that more sub-pixels can be arranged in a unit area, and the pixel density (pixels per inch, PPI) of the display panel can be further improved.

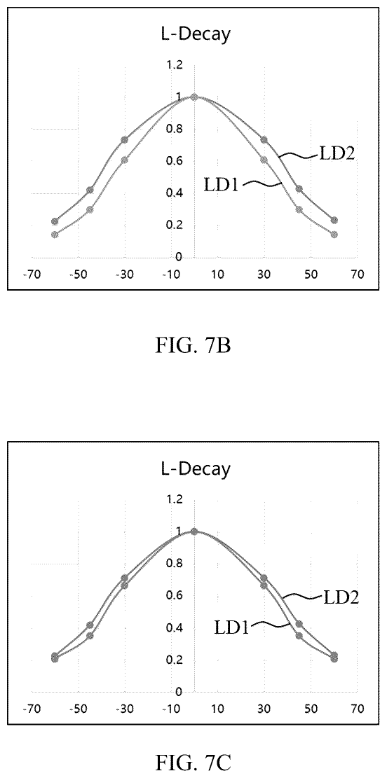

FIG. 7A to FIG. 7C illustrate the luminance variation curve (L-Decay curve) LD1 of the blue light-emitting region (e.g., corresponding to the light-emitting region R1) and the luminance variation curve LD2 of the red light-emitting region (e.g., corresponding to the light-emitting region R3) in Embodiment 1, Embodiment 2 and Embodiment 5 under different viewing angles. It should be understood that the luminance of the light-emitting regions shown in FIGS. 7A to 7C refers to the luminance of light exited from the light exiting surface of the display panel after the light emitted from the light-emitting regions R1 to R3 passing through the optical adjustment layer and the antireflection layer.

In some embodiments, first exiting light and second exiting light that are respectively emitted from the first light-emitting region (e.g., blue light-emitting region R1) and the second light-emitting region (e.g., green light-emitting region R2 or red light-emitting region R3) and each passing through the optical adjustment layer and the antireflection layer respectively have a first luminance attenuation value and a second luminance attenuation value at a nonzero-degree viewing angle. The first luminance attenuation value is a percentage of a difference between a luminance of the first exiting light at the nonzero-degree viewing angle and an initial luminance of the first exiting light at a zero-degree viewing angle to the initial luminance, and the second luminance attenuation value is a percentage of a difference between a luminance of the second exiting light at the nonzero-degree viewing angle and an initial luminance of the second exiting light at a zero-degree viewing angle to the initial luminance. At the same viewing angle, the first luminance attenuation value is greater than the second luminance attenuation value.

For example, at a viewing angle of 30 degrees, the first luminance attenuation value ranges from 32% to 40%, and the second luminance attenuation value ranges from 17% to 28%; and at a viewing angle of 45 degrees, the first luminance attenuation value ranges from 62% to 70%, and the second luminance attenuation value ranges from 55% to 57.5%. In some embodiments, at the same viewing angle, the difference between the first luminance attenuation value and the second luminance attenuation value is equal to or less than 7.5%.

For example, referring to Table 1, Table 2 and FIGS. 7A to 7C, in Embodiment 1, Embodiment 2 and Embodiment 5, the offset distances x1, x2 and x3 between light-shielding edges and the spacer edges corresponding to respective light-emitting regions are different, wherein the offset distances x1, x2 and x3 between respective edges corresponding to light-emitting regions R1 to R3 in Embodiment 1 are all 4 m; the offset distances x1, x2 and x3 between respective edges corresponding to light-emitting regions R1 to R3 in Embodiment 2 are relatively small and are all 2 m; while in Embodiment 5, the offset distance x1 between respective edges corresponding to the light-emitting region R1 (e.g., blue light-emitting region) is set to be different from (e.g., greater than) the offset distances x2 and x3 between respective edges corresponding to other light-emitting regions R2 and R3 (e.g., green light-emitting region and red light-emitting region), for example, x1 is 4 m, while x2 and x3 are 1.5 m. In some embodiments, the viewing angle luminance attenuation degrees are similar in the red light-emitting region and the green light-emitting region, and hereinafter the red light-emitting region is taken to be compared with the blue light-emitting region by way of example.

As shown in FIG. 7A to FIG. 7C, in the embodiments, the viewing angle luminance attenuation of the blue light-emitting region is greater than that of the red light-emitting region; that is to say, at a nonzero-degree viewing angle, the degree of luminance attenuation of the blue light-emitting region is greater than that of the red light-emitting region. The degree of luminance attenuation is the degree to which the luminance at the viewing angle is reduced compared with the initial luminance at zero-degree viewing angle. In some embodiments, since the optical adjustment layer substantially only enhances the luminance of the blue light-emitting region while substantially has no effect on the luminance of the red and green light-emitting regions, the viewing angle luminance attenuation of the blue light-emitting region is obviously greater than that of other light-emitting regions (e.g., the red and green light-emitting regions). That is to say, under the same nonzero viewing angle, the viewing angle luminance attenuation of the blue light-emitting region is greater than that of other light-emitting regions (e.g., red and green light-emitting regions).

Comparing Embodiment 1 and Embodiment 2, as compared with Embodiment 1, in Embodiment 2, with the decrease of offset distances x1, x2 and x3 between light-shielding edges and spacer edges corresponding to respective light-emitting regions, the degrees of luminance attenuation of the corresponding light-emitting regions such as blue light-emitting region and red light-emitting region are all further increased. This is because the decrease of the offset distance between the light-shielding edge and the spacer edge represents that the area of the light-shielding layer is relatively increased, and the size of the light-transmitting opening of the light-shielding layer is reduced, which further increases the viewing angle luminance attenuations of the respective light-emitting regions. That is to say, for each light-emitting region, the offset distance between the corresponding light-shielding edge and spacer edge is negatively correlated with the degree of viewing angle luminance attenuation of the light-emitting region. For example, the greater the offset distance between the corresponding light-shielding edge and spacer edge, the smaller the degree of luminance attenuation of the light-emitting region at a nonzero viewing angle; while the smaller the offset distance between the corresponding light-shielding edge and spacer edge, the greater the degree of luminance attenuation of the light-emitting region at a nonzero viewing angle.

In addition, as shown in FIGS. 7A and 7B, the difference between the luminance attenuation curve LD2 of the red light-emitting region shown in FIG. 7B and the luminance attenuation curve LD2 of the red light-emitting region shown in FIG. 7A is greater than the difference between the luminance attenuation curve LD1 of the blue light-emitting region shown in FIG. 7B and the luminance attenuation curve LD1 of the blue light-emitting region shown in FIG. 7A. In other words, under the condition that the offset distance between the light-shielding edge and the spacer edge is reduced by the same extent, the luminance attenuation of the red light-emitting region due to the reduction of the offset distance x3 between the light-shielding edge and the spacer edge is greater than the luminance attenuation of the blue light-emitting region due to the reduction of the offset distance x1 between the light-shielding edge and the spacer edge. In some embodiments, this is because other light-emitting regions (e.g., red and green light-emitting region) themselves have relatively high luminance as compared with the blue light-emitting region, and hence are more affected by the above-mentioned offset distance (that is, the size of the light-transmitting opening of the light-shielding layer). In other words, the change of the offset distance between the light-shielding edge and the spacer edge has less influence on the viewing angle luminance attenuation of the blue light-emitting region as compared with the influence thereof on the viewing angle luminance attenuation of other light-emitting regions (e.g., red and green light-emitting regions).

Compared with Embodiment 1, in Embodiment 2, the difference between the luminance attenuation curves LD1 and LD2 of the blue light-emitting region and the red light-emitting region becomes smaller, so that the color deviation under different viewing angles can be reduced.

In Embodiment 5, the offset distances x1, x2 and x3 of the corresponding light-emitting regions are set as 4 μm, 1.5 μm and 1.5 μm, respectively. As shown in FIG. 7C, compared with FIGS. 7A and 7B, the viewing angle luminance attenuation curve LD1 of the blue light-emitting region and the viewing angle luminance attenuation curve LD2 of the red light-emitting region in FIG. 7C are closer, that is, the difference between them is smaller. This is because the offset distance x1 of the blue light-emitting region is set to be relatively large, which relatively reduces (e.g., minimizes) the viewing angle luminance attenuation of the light-emitting region caused by the offset distance; while the offset distance x3 of the red light-emitting region is set to be relatively small, which relatively increases the viewing angle luminance attenuation of the light-emitting region caused by the offset distance; that is, for the blue light-emitting region, the offset distance, which is an impact factor for viewing angle luminance attenuation, is reduced, while for the red light-emitting region, the offset distance, which is an impact factor for viewing angle luminance attenuation, is increased. Since the degree of viewing angle luminance attenuation of the blue light-emitting region per se is greater than that of the red light-emitting region, the difference between the viewing angle luminance attenuation of the blue light-emitting region and the viewing angle luminance attenuation of the red light-emitting region is reduced after the above-mentioned settings of offset distances for respective light-emitting regions, so that the color deviation under different viewing angles can be reduced.

Therefore, in Embodiment 5, the offset distance x1 corresponding to the blue light-emitting region is set to be relatively large, so that the influence of the offset distance on the viewing angle luminance attenuation of the blue light-emitting region can be minimized on the premise of satisfying the light-shielding requirements and achieving an appropriate reflectivity of the panel by the light-shielding layer; at the same time, the offset distance x2/x3 of other light-emitting region (e.g., green or red light-emitting region) is set to be relatively small, which increases the viewing angle luminance attenuation caused by the offset distance of other light-emitting regions, thereby narrowing the difference between the viewing angle luminance attenuation of the blue light-emitting region and that of other light-emitting regions such as red and green light-emitting regions, thereby further reducing the color deviation under different viewing angles, and maximizing the matching of luminance and color under different viewing angles can be achieved. On the other hand, by separately setting the offset distances in different regions, the overall area of the light-shielding layer can be ensured, so that the strong absorption of external ambient light can be realized, the reflectivity of the display panel can be reduced, and the contrast and display quality of the display screen can be improved.

In some embodiments, FIG. 8 illustrates a power consumption curve P and a luminance curve L of the display panel in Embodiment 3 where the optical adjustment layer has different transmittances for the light-emitting region R1. It should be noted that the luminance curve L described below with reference to FIG. 8 reflects the luminance of the light-emitting region corresponding to the light-emitting region R1 of the display panel (i.e., the luminance of the light that is emitted from the light-emitting region R1 and exits from the light exiting surface of the display panel after passing through the optical adjustment layer and the antireflection layer), and the transmittance of the optical adjustment layer described below with reference to FIG. 8 refers to the transmittance of the optical adjustment layer for the light emitted from the light-emitting region R1, which is, for example, a region emitting blue light.

Referring to FIG. 8, in some embodiments, within a certain range, for example, within a range where the transmittance of the optical adjustment layer is smaller than or equal to about 50% (e.g., smaller than or equal to about 55%), as the transmittance of the optical adjustment layer increases, the luminance of the display panel also increases, and the device power consumption decreases therewith. Beyond this range, for example, within a range where the transmittance of the optical adjustment layer is greater than or equal to about 50% (e.g., greater than or equal to about 55%), as the transmittance of the optical adjustment layer increases, the luminance of the display panel decreases therewith, and the device power consumption increases. When the transmittance of the optical adjustment layer is about 55%, the luminance of the display panel reaches the maximum value and the device power consumption is minimized. However, the present disclosure is not limited thereto.

With reference to FIG. 2A and FIG. 8, for example, apart of the light emitted by the light-emitting region R1, after passing through the optical adjustment layer 20, at least partially passes through the antireflection layer 22 and exits. As described above, the antireflection layer 22 is used to prevent from or reduce the situation that the ambient light incident into the display panel is reflected by a material layer of the display panel and exits from the light exiting surface of the display panel, thereby reducing the reflectivity of the display panel and improving the display contrast. However, the antireflection layer 22 may also block the light emitted from the light-emitting regions of the display panel to some extent. For example, a polarizing layer is disposed in the antireflection layer 22, and the polarizing layer has a transmittance not smaller than 40%, for example, about 50%, for example, about 55% for light in a wavelength range of 460 nm to 630 nm, which overlaps with the wavelength range of each of blue, green and red light. That is, in the case where a conventional display panel is not provided with an optical adjustment layer, the light emitted from the respective light-emitting regions cannot be completely transmitted through the antireflection layer, and the transmittance is, for example, about 50% or 55%. In the embodiment of the present disclosure, an optical adjustment layer is disposed between the light-emitting region and the antireflection layer, and the optical adjustment layer is configured to have a certain transmittance and reflectivity for light (e.g., blue light) emitted from the light-emitting region R1. In some embodiments, the transmittance and reflectivity of the optical adjustment layer for light are in a relationship of “as one decreases, the other one increases”, that is, the higher the transmittance, the lower the corresponding reflectivity; the lower the transmittance, the higher the corresponding reflectivity.

In the embodiment of the present disclosure, by configuring the optical adjustment layer to have a transmittance and a reflectivity in an appropriate range for light (e.g., blue light) emitted from the light-emitting region R1, the loss of the light A emitted from the light-emitting region R1 is minimized, thereby improving the luminance of the corresponding region and further reducing the device power consumption.

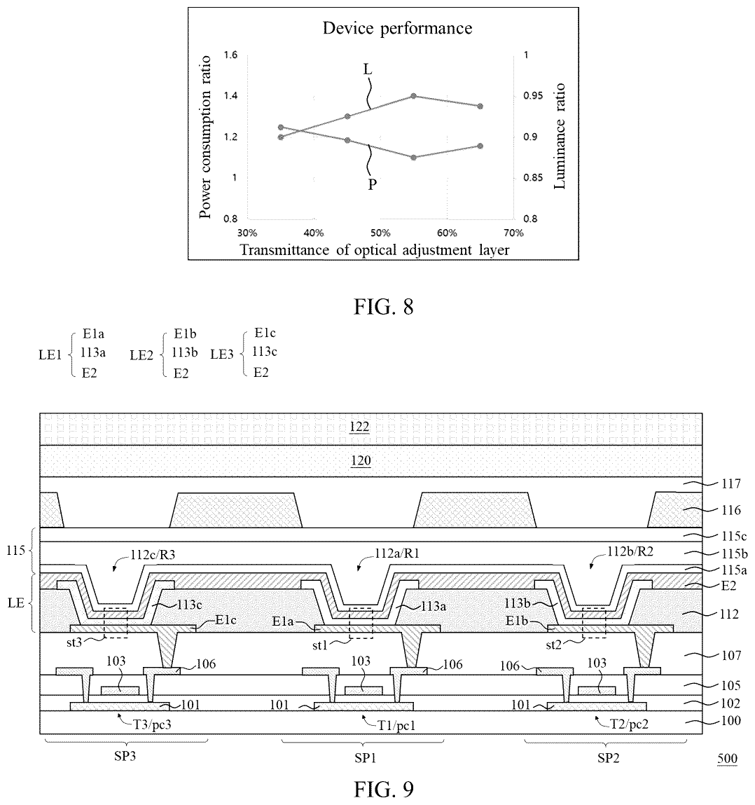

FIG. 9 illustrates a schematic cross-sectional view of a display panel according to some embodiments of the present disclosure.

Referring to FIG. 9, in some embodiments, the display panel 500 includes abase substrate 100 and a plurality of pixel units arranged in an array on the base substrate 100, and each pixel unit may include a plurality of sub-pixels for displaying different colors, such as sub-pixels SP1, SP2 and SP3. For example, the sub-pixels SP1, SP2 and SP3 may be a blue sub-pixel, a green sub-pixel and a red sub-pixel configured to display blue color, green color and red color, respectively. In some embodiments, each sub-pixel includes a light-emitting device structure and a pixel circuit connected to each other, and the pixel circuit is configured to drive the light-emitting device structure to emit light.

In some embodiments, the light-emitting device structure of each sub-pixel at least includes a first electrode, a second electrode and a light-emitting layer located between the first electrode and the second electrode. The pixel circuit of each sub-pixel may include thin film transistor(s) and capacitor(s), and may adopt any suitable structure, for example, may be a pixel circuit such as 2T1C, 6T1C, 7T1C, 8T1C, 10T1C, 6T2C, 7T2C, 8T2C, or 10T2C pixel circuit. It should be understood that, the pixel circuits of the respective sub-pixels can be configured and adjusted according to product designs and requirements.

For example, the sub-pixel SP1 includes a light-emitting device structure LE1 and a pixel circuit pc1, the sub-pixel SP2 includes a light-emitting device structure LE2 and a pixel circuit pc2, and the sub-pixel SP3 includes a light-emitting device structure LE3 and a pixel circuit pc3. The light-emitting device structures LE1-LE3 are located at the light-emitting device layer LE, and the pixel circuits pc1-pc3 may be located at a side of the light-emitting device layer LE close to the base substrate 100. The figure schematically illustrates that the pixel circuits pc1, pc2 and pc3 each include one thin film transistor T1, T2 and T3, and it should be understood that the pixel circuits pc1-pc3 may each further include one or more other thin film transistors and capacitor(s) (not shown).

In some embodiment, the thin film transistors T1-T3 each include an active layer 101, a gate electrode 103, a gate insulating layer, and a source/drain electrode 106 disposed on the base substrate 100. In some embodiments, the active layer 101 is disposed on a side of the base substrate 100, and the insulating layer 102 is disposed on the base substrate 100 and covers the sidewalls of the active layer 101 and the surface thereof away from the base substrate 100. Some portions of the insulating layer 102 are located between the active layers 101 and the gate electrodes 103, respectively, so as to serve as gate insulating layers of the thin film transistors T1-T3. The active layer 101 includes a source region, a drain region and a channel region between the source region and the drain region. The source/drain electrode 106 includes a source electrode and a drain electrode respectively connected to the source region and the drain region of the active layer 101. It should be appreciated that FIG. 9 illustrates the case where the thin film transistors T1-T3 have top-gate structures by way of example, but the present disclosure is not limited thereto. The thin film transistors T1-T3 may also have bottom-gate structures or dual-gate structures.

In some embodiments, the display panel 500 includes a spacer layer 112. The spacer layer 112 includes a plurality of sub-pixel openings 112a, 112b, and 112c for defining the light-emitting regions R1, R2, and R3 of the sub-pixels SP1, SP2, and SP3, and portions of the light-emitting device structures LE1, LE2, and LE3 corresponding to the sub-pixel openings 112a, 112b, and 112c constitute the light-emitting regions R1, R2, and R3, respectively. The portion of the light-emitting device structure corresponding to each sub-pixel opening is or includes a portion thereof whose orthographic projection on the base substrate 100 is located within the range of orthographic projection of the sub-pixel opening on the base substrate. In some embodiments, the spacer layer 112 may also be referred to as a pixel defining layer (PDL).

In some embodiments, the light-emitting device layer LE includes a first electrode layer, a light-emitting layer and a second electrode layer, wherein the light-emitting layer is located between the first electrode layer and the second electrode layer; the first electrode layer may be connected to the pixel circuit; the spacer layer 112 may be located at a side of the first electrode layer away from the base substrate 100, and exposes at least part of the first electrode layer; the light-emitting layer is located at a side of the first electrode layer away from the base substrate 100 and may be arranged along the sub-pixel openings of the spacer layer 112, and may also be arranged along the surface of the spacer layer 112 at a side away from the base substrate 100; the second electrode layer may be located at a side of the light-emitting layer away from the first electrode layer.

In some embodiments, the first electrode layer includes first electrodes E1a, E1b, E1c spaced apart from each other, and the first electrode layer may include a material with high work function, such as a metal, a metal oxide, or combinations thereof. For example, when the display panel 500 is a top-emission structure as shown in FIG. 9, the first electrode layer may be a composite structure including a metal layer and a transparent oxide layer (e.g., a metal oxide layer), such as “Ag/ITO”, “Ag/IZO”, or the like. For example, the thickness of the metal layer may range from 80 nm to 100 nm, and the thickness of the metal oxide layer may range from 5 nm to 10 nm. For example, the first electrode may be an anode with an average reflectivity of about 85% to 95% for light in the visible light region, and the first electrode can also be used as a reflective electrode, for example, which can reflect the light emitted by each light-emitting region and reflected by the optical adjustment layer 120. It should be appreciated that the display panel with the top-emission structure shown in FIG. 9 is only for illustration, and the present disclosure is not limited thereto. In some other embodiments, the display panel may also have a bottom-emission structure, and the first electrode layer may include an transparent oxide, for example, may include a metal oxide such as ITO, IZO, and the thickness of the first electrode layer may range from 80 nm to 200 nm, for example.

In some embodiments, the light-emitting layer may include light-emitting layers 113a, 113b and 113c; each light-emitting layer may include a host material and a doping material, the host material may be, for example, a wide-band gap material such as a compound including at least one group of carbazole group, carboline group, spirofluorenyl group, fluorenyl group, silicon group and phosphinoxy group; the doping material is, for example, a luminescent material such as phosphorescent material, fluorescent material or the like. For example, the light-emitting layer 113a may be a blue light-emitting layer and at least include a host material and a doping material, and the doping material may include a fluorescent material, a delayed fluorescent material or a phosphorescent material; The light-emitting layer 112b may be a green light-emitting layer and at least include a host material and a doping material, and the doping material may include a delayed fluorescent material or a phosphorescent material. The light-emitting layer 112c may be a red light-emitting layer and at least includes a host material and a doping material, and the doping material may include a delayed fluorescent material or a phosphorescent material. In some embodiments, the thicknesses of the light-emitting layers 113a-113c may be the same as or different from each other, for example, the thickness of the light-emitting layer 113a ranges from about 15 nm to 25 nm; the thickness of the light-emitting layer 113b ranges from about 25 nm to 40 nm; the thickness of the light-emitting layer 113c ranges from about 25 nm to 40 nm. It should be appreciated that, the thickness of the light-emitting layer refers to the thickness thereof in the direction perpendicular to the main surface of the base substrate.

In some embodiments, the light-emitting layers 113a-113c may be arranged along the surfaces of the corresponding sub-pixel openings 112a-112c of the spacer layer 112 to cover the parts of the corresponding first electrodes E1a-E1c exposed by the sub-pixel openings and at least part of the sidewall of the spacer layer 112; and the light-emitting layers 113a-113b may further extend to cover a part of the surface (or may be referred to as the top wall) of the spacer layer 112 at a side away from the base substrate 100. In other words, the light-emitting layers 113a, 113b, and 113c each include at least a portion located in the corresponding light-emitting region R1, R2 or R3, and may further include an extended portion located outside the corresponding light-emitting region. For example, the respective extended portions of the light-emitting layers 113a-113c may be located outside the respective light-emitting regions and landing on the respective sidewalls and/or top walls of the spacer layer 112.

For example, each of the light-emitting layers 113a, 113b, and 113c may be formed by an evaporation process, which may include providing a fine metal mask (FMM) with pattern openings at a side of the spacer layer after forming the sub-pixel openings, such that the pattern openings are located at positions corresponding to the respective sub-pixel openings, and depositing evaporation materials (i.e., light-emitting layer materials) on the spacer layer through the pattern openings of the FMM to form the light-emitting layers. In some embodiments, the size of the pattern opening is greater than that of the corresponding sub-pixel opening, which can facilitate the alignment of the pattern opening and the sub-pixel opening, and can ensure that the light-emitting layer can be effectively formed in the light-emitting region defined by the sub-pixel opening. In some embodiments, the area of the orthographic projection of each of the light-emitting layers 113a, 113b and 113c on the base substrate 100 may be greater than the area of the orthographic projection of the corresponding light-emitting region R1, R2 or R3 on the base substrate 100; the orthographic projection of each of the light-emitting regions R1, R2 and R3 on the base substrate 100 may be located within the range of orthographic projection of the corresponding light-emitting layer 113a, 113b or 113c on the base substrate 100.

In some embodiments, the second electrode layer E2 may include: a metal material, such as Mg, Ag, Al, or the like; a metal alloy such as Mg/Ag or the like; a metal oxide such as ITO, IZO, IGZO or the like, or the like. The second electrode layer E2 may serve as a cathode and may have semi-transmissive or transmissive properties. The second electrode layer E2 may extend continuously in the respective sub-pixel regions and may serve as a common cathode. In some embodiments, taken the case where the display panel 500 is a top-emission display panel as an example, the second electrode layer E2 may be a translucent cathode, and may be formed by evaporating a metal film (e.g., Mg film, Ag film, Al film) ranging from 10 nm to 20 nm; alternatively, the second electrode layer E2 may be formed by using a metal alloy such as Mg:Ag, and the preferred ratio of Mg:Ag may range from 3:7 to 1:9, so that the metal film layer has an appropriate transmittance; for example, the reference range of the transmittance of the metal film layer at wavelength of 530 nm may be 50% to 60%, thus forming a translucent cathode. In some embodiments, the second electrode layer E2 may also be a transparent cathode formed of transparent oxide such as ITO, IZO, IGZO or the like. However, the present disclosure is not limited thereto.

That is to say, in the case that the display panel 500 has a top-emission structure as shown in FIG. 9, the optical adjustment layer 120 is disposed on a side of the light-emitting device layer LE away from the base substrate 100, and the second electrode layer E2 is closer to the optical adjustment layer 120 than the first electrode layer to the optical adjustment layer 120; the second electrode layer can transmit light, such as the light emitted by the light-emitting layers; the first electrode layer can be used as a reflective electrode to reflect light, for example, can reflect the light emitted by the light-emitting regions, reflected by the optical adjustment layer and irradiated on the first electrode layer, and can reflect the light back to the optical adjustment layer. However, the present disclosure is not limited thereto.

In some other embodiments, the display panel may also have a bottom-emission structure, and the first electrode layer may be closer to the optical adjustment layer than the second electrode layer E2 to the optical adjustment layer. In this case, the first electrode layer may be configured to transmit the light emitted by the respective light-emitting layers, and the second electrode layer may be configured to have a certain reflectivity and used as a reflective electrode.

The light-emitting device structure LE1 may at least include a first electrode E1a, a light-emitting layer 113a, and a part of a second electrode layer E2 (e.g., a part corresponding to the sub-pixel opening 112a); the light-emitting device structure LE2 may at least include a first electrode E1b, a light-emitting layer 113b, and a part of a second electrode layer E2 (e.g., a part corresponding to the sub-pixel opening 112b); the light-emitting device structure LE3 may at least include a first electrode E1c, a light-emitting layer 113c, and a part of a second electrode layer E2 (e.g., a part corresponding to the sub-pixel opening 112c).

Still referring to FIG. 9, in some embodiments, the encapsulation layer 115 may include a first encapsulation layer 115a, a second encapsulation layer 115b, and a third encapsulation layer 115c. For example, the first encapsulation layer 115a and the third encapsulation layer 115c may include inorganic materials, which may be at least one selected from the group consisted of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride and lithium fluoride. For example, the second encapsulation layer 115b may include an organic material, and the organic material may be selected from at least one of an acrylic resin, a methacrylic acid resin, polyisoprene, a vinylite resin, an epoxy resin, a polyurethane resin, a cellulose resin and a perylene resin.

In some embodiments, the refractive index of at least two of the first to third encapsulation layers 115a to 115c is greater than 1.65; the coverage area of the second encapsulation layer 115b may not be greater than those of the first and third encapsulation layers 115a and 115c, so as to protect the display panel from erosion by water and oxygen. The number of layers and structure of the encapsulation layer 115 shown in FIG. 9 and the above-mentioned materials are only examples, and the present disclosure is not limited thereto.

In some embodiments, a touch structure layer may be further disposed between the encapsulation layer and the planarization layer of the display panel 50 or 500, so as to realize the touch function of the display panel. The touch structure may be any type of touch structure such as self-capacitive touch structure or mutual-capacitive touch structure. For example, the self-capacitive touch structure or the mutual-capacitive touch structure may include at least one conductive layer, but the specific type and structure of the touch structure are not limited in the embodiment of the present disclosure.

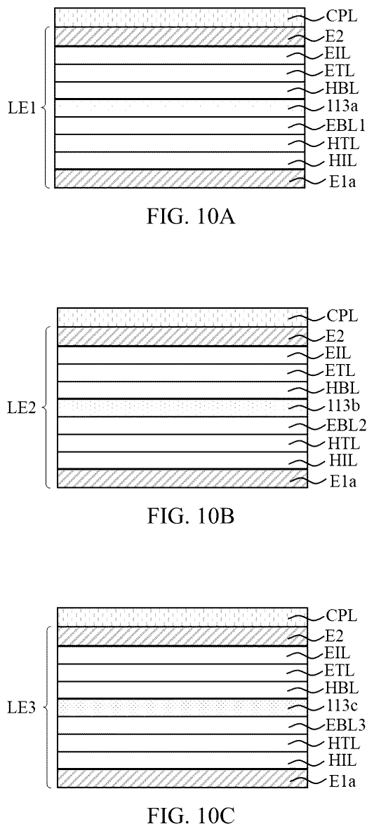

FIGS. 10A to 10C illustrate schematic cross-sectional views of a partial region in a display panel according to some embodiments of the present disclosure. For example, FIGS. 10A to 10C respectively correspond to more specific, structural diagrams of regions st1, st2 and st3 in the display panel of FIG. 9 in some other embodiments. These regions include parts of the light-emitting device structures LE1 to LE3, respectively.

As shown in FIG. 10A to FIG. 10C, in some embodiments, in the direction perpendicular to the main surface of the base substrate 100, the light-emitting device structure LE1 may include a first electrode E1a, a hole injection layer HIL, a hole transport layer HTL, an exciton barrier layer EBL1, a light-emitting layer 113a, a hole barrier layer HBL, an electron transport layer ETL, an electron injection layer EIL, and a second electrode E2 from bottom to top; the light-emitting device structure LE2 may include a first electrode E1a, a hole injection layer HIL, a hole transport layer HTL, an exciton barrier layer EBL2, a light-emitting layer 113b, a hole barrier layer HBL, an electron transport layer ETL, an electron injection layer EIL, and a second electrode E2 from bottom to top; the light-emitting device structure LE3 may include a first electrode E1a, a hole injection layer HIL, a hole transport layer HTL, an exciton barrier layer EBL3, a light-emitting layer 113c, a hole barrier layer HBL, an electron transport layer ETL, an electron injection layer EIL, and a second electrode E2 from bottom to top.

In some embodiments, the hole injection layer HIL is used to reduce the hole injection barrier and improve the hole injection efficiency. The hole injection layer HIL may be formed by forming a single-layer film with a materials such as HATCN, CuPc, or the like. Alternatively, the hole injection layer HIL may also be formed by doping the hole transport material with a P-type dopant. For example, the material of the hole injection layer HIL may include NPB: F4TCNQ, TAPC: MnO₃, or the like. In some embodiments, the thickness of the hole injection layer HIL may range from 5 nm to 20 nm, and the doping concentration of the P-type dopant may be about 0.5% to 10%. However, the present disclosure is not limited thereto.

In some embodiments, the hole transport layer HTL may be formed by an evaporation process using a carbazole-based material with high hole mobility rate. For example, the highest occupied molecular orbital (HOMO) energy level of the material of the hole transport layer HTL is required to be in a range of −5.2 eV to −5.6 eV. For example, the thickness of the hole transport layer HTL may range from about 100 nm to 200 nm. However, the present disclosure is not limited thereto.

In some embodiments, the exciton barrier layer may be configured to transfer holes and to block electrons and excitons generated in the corresponding light-emitting layer. For example, the light-emitting device structures LE1, LE2 and LE3 may be configured to emit blue light, green light and red light, respectively, and the exciton barrier layers EBL1, EBL2 and EBL3 may be a blue exciton barrier layer, a green exciton barrier layer and a red exciton barrier layer, respectively. The thicknesses of the exciton barrier layers EBL1-ELB3 may be the same as or different from each other. For example, the thickness of the blue exciton barrier layer EBL1 may range from about 1 nm to 10 nm, and the thickness of the green exciton barrier layer EBL2 may range from about 15 nm to 30 nm; the thickness of the red exciton barrier layer EBL3 may range from about 40 nm to 60 nm. However, the present disclosure is not limited thereto.

In some embodiments, the hole barrier layer HBL is configured to transfer electrons, and to block holes and excitons generated in the light-emitting layer. For example, the thickness of the hole barrier layer HBL may range from about 2 nm to 10 nm, but the present disclosure is not limited thereto.

In some embodiments, the material of the electron transport layer ETL may be prepared by blending a material such as thiophene derivatives, imidazole derivatives or azine derivatives with lithium quinolate, wherein the proportion of lithium quinolate may range from about 30% to 70%, and the thickness of the electron transport layer ETL may range from about 20 nm to 40 nm.

In some embodiments, the material of the electron injection layer EIL may include LiF, LiQ, Yb, Ca, or the like, and may be formed by, for example, an evaporation process; the thickness of the electron injection layer EIL may range from about 0.5 nm to 2 nm.

Referring to FIG. 9 and FIGS. 10A to 10C, in some embodiments, the display panel 500 further includes a light extraction layer CPL, which is disposed on the light exiting side of the light-emitting device layer and may be arranged between the light-emitting device layer LE and the encapsulation layer 115. For example, the light extraction layer CPL may be disposed between the second electrode layer (e.g., cathode) E2 of the light-emitting device layer LE and the encapsulation layer 115. In some embodiments, the difference between the refractive index of the light extraction layer CPL and the refractive index of a material layer (e.g., the first encapsulation layer 115a) in the encapsulation layer 115 that is immediately adjacent to (i.e., in contact with) the light extraction layer CPL is equal to or more than 0.1. By providing the light extraction layer CPL, the light extraction efficiency of the light-emitting device layer can be improved.

In some embodiments, the present disclosure provides a display device including the display panel described in any one of the above embodiments.

In the embodiment of the present disclosure, by providing the optical adjustment layer and the antireflection layer, while the lifespan of blue light is guaranteed, the light extraction efficiency of blue light can be improved and the luminance of blue light regions can be enhanced, and the device power consumption of the display panel can be reduced, without substantially affecting the light emission of other regions. For example, compared with the traditional OLED devices, the luminance of blue light of the display panel provided by the embodiment of the present disclosure can be improved by 20% or more, and the device power consumption can be reduced by 8% or more. In addition, since the optical adjustment layer enhances the luminance of blue light, the light-emitting area of the blue sub-pixel can be set relatively small on the premise of ensuring the lifespan of blue light, and the overall area of the blue sub-pixel can be reduced, so that more sub-pixels can be disposed in a unit area, thereby increasing the pixel density. In some embodiments, the total aperture ratio of the display panel can be reduced to be equal to or greater than 15%. For example, the pixel density of the display panel provided by the embodiment of the present disclosure may be not lower than 460 PPI, and may reach 520 PPI or above, for example.

On the other hand, in the embodiment of the present disclosure, by providing the antireflection layer, the light-shielding layer and setting the offset distance between the light-shielding edge and the spacer edge, the display panel can have a low reflectivity and high contrast. For example, the overall reflectivity of the display panel does not exceed 7%, and the display contrast can exceed 1000000:1.

The following statements should be noted:
(1) The drawings of the present disclosure involve only the structure(s) in connection with the embodiment(s) of the present disclosure, and other structure(s) can be referred to common design(s).
(2) In case of no conflict, features in one embodiment or in different embodiments can be combined to obtain new embodiments.

What have been described above are only specific implementations of the present disclosure, the protection scope of the present disclosure is not limited thereto. Any modifications or substitutions easily occur to those skilled in the art within the technical scope of the present disclosure should be within the protection scope of the present disclosure. Therefore, the protection scope of the present disclosure should be based on the protection scope of the claims.

1. A display panel, comprising a plurality of sub-pixels arranged in an array, and comprising:
a base substrate;
a light-emitting device layer, disposed on a side of the base substrate, wherein the light-emitting device layer comprises a plurality of light-emitting regions configured to emit light of different colors, the plurality of light-emitting regions respectively correspond to the plurality of sub-pixels and comprise a first light-emitting region and a second light-emitting region, wherein the first light-emitting region is configured to emit light with a first color and in a first wavelength range, and the second light-emitting region is configured to emit light with a second color and in a second wavelength range;
an optical adjustment layer, disposed on a light exiting side of the light-emitting device layer, wherein the optical adjustment layer is configured to have a transmittance for light in the first wavelength range being smaller than a transmittance thereof for light in the second wavelength range, and to have a reflectivity for light in the first wavelength range being greater than a reflectivity thereof for light in the second wavelength range, wherein the optical adjustment layer at least covers the first light-emitting region, and an orthographic projection of the first light-emitting region on the base substrate is located within an orthographic projection of the optical adjustment layer on the base substrate; and
an antireflection layer, disposed on a side of the optical adjustment layer away from the light-emitting device layer.

2. The display panel according to claim 1, wherein a wavelength of the first wavelength range is smaller than a wavelength of the second wavelength range.

3. The display panel according to claim 1, wherein the optical adjustment layer has a transmittance in a range of 30% to 70% for light in the first wavelength range, and has a reflectivity in a range of 30% to 70% for light in the first wavelength range.

4. The display panel according to claim 1, wherein the plurality of light-emitting regions further comprise a third light-emitting region configured to emit light with a third color and in a third wavelength range, and
the optical adjustment layer is configured to have a transmittance for light in the third wavelength range being greater than a transmittance thereof for light in the first wavelength range, and to have a reflectivity for light in the third wavelength range being smaller than a reflectivity thereof for light in the first wavelength range.

5. The display panel according to claim 4, wherein the optical adjustment layer has a transmittance greater than 80% and a reflectivity smaller than 15% for at least part of light in the second wavelength range and the third wavelength range.

6. (canceled)

7. The display panel according to claim 4, wherein
the plurality of sub-pixels comprise a red sub-pixel, a green sub-pixel and a blue sub-pixel, and the first light-emitting region, the second light-emitting region and the third light-emitting region are light-emitting regions of the blue sub-pixel, the green sub-pixel and the red sub-pixel respectively; and
an aperture ratio of the blue sub-pixel is greater than or equal to an aperture ratio of the red sub-pixel, an aperture ratio of the green sub-pixel is greater than or equal to an aperture ratio of the red sub-pixel, the aperture ratio of the red sub-pixel is smaller than or equal to 8%, and a maximum aperture ratio of the blue sub-pixel and the green sub-pixel is smaller than or equal to 10%.

8. The display panel according to claim 4, wherein the optical adjustment layer is configured such that a color deviation value CIEx or CIEy of light obtained after incident light emitted from the plurality of light-emitting regions passing through the optical adjustment layer with relative to the incident light is smaller than or equal to 0.005.

9. (canceled)

10. The display panel according to claim 4, wherein the optical adjustment layer is a continuous film layer, and orthographic projections of the second light-emitting region and the third light-emitting region on the base substrate both are also located within the orthographic projection of the optical adjustment layer on the base substrate.

11. The display panel according to claim 4, wherein orthographic projections of the first light-emitting region, the second light-emitting region and the third light-emitting region on the base substrate are located within an orthographic projection of the antireflection layer on the base substrate.

12. The display panel according to claim 1, wherein the optical adjustment layer is configured to transmit a first part of light among light emitted from the first light-emitting region and reflect a second part of light among the light emitted from the first light-emitting region, and
the antireflection layer is configured to transmit the first part of light.

13. The display panel according to claim 12, wherein
the optical adjustment layer is further configured to reflect the second part of light to at least one film layer located between the optical adjustment layer and the base substrate, and the second part of light is further reflected by the at least one film layer and emitted to the optical adjustment layer as first sub-light;
the optical adjustment layer is configured to transmit at least part of the first sub-light; and
the antireflection layer is configured to transmit the at least part of the first sub-light.

14. The display panel according to claim 13, wherein the light-emitting device layer comprises a reflective electrode, and the at least one film layer that reflects the second part of light comprises the reflective electrode.

15. The display panel according to claim 13, wherein the first part of light has a first polarization state, the second part of light has a second polarization state, and a polarization state of the second part of light is changed after being reflected by the at least one film layer, so that the first sub-light has the first polarization state.

16. The display panel according to claim 15, wherein the antireflection layer at least comprises a polarization conversion layer and a polarizing layer, the polarizing layer is located at a side of the polarization conversion layer away from the optical adjustment layer, and light with the first polarization state, after transmitting through the polarization conversion layer, have a polarization direction parallel to a polarization direction of the polarizing layer.

17. The display panel according to claim 16, further comprising a light-absorbing layer, and the light-absorbing layer is located at a side of the polarizing layer away from the polarization conversion layer.

18. The display panel according to claim 1, wherein the orthographic projection of the optical adjustment layer on the base substrate is located within a range of an orthographic projection of the antireflection layer on the base substrate.

19. The display panel according to claim 2, further comprising:
a spacer layer, defining a plurality of sub-pixel openings, wherein the plurality of light-emitting regions are respectively located in corresponding sub-pixel openings; and
a light-shielding layer, located between the spacer layer and the optical adjustment layer in a direction perpendicular to a main surface of the base substrate, wherein the light-shielding layer has a plurality of light-transmitting openings, the plurality of sub-pixel openings are in one-to-one correspondence with the plurality of light-transmitting openings, and an orthographic projection of each of the plurality of sub-pixel openings on the base substrate is located within a range of an orthographic projection of a corresponding one of the plurality of light-transmitting openings on the base substrate.

20. The display panel according to claim 19, wherein
the spacer layer has a first sub-pixel opening corresponding to the first light-emitting region and a second sub-pixel opening corresponding to the second light-emitting region, and the light-shielding layer has a first light-transmitting opening corresponding to the first light-emitting region, and a second light-transmitting opening corresponding to the second light-emitting region;
the spacer layer has a first spacer edge defining the first sub-pixel opening and a second spacer edge defining the second sub-pixel opening, and the light-shielding layer has a first light-shielding edge defining the first light-transmitting opening and a second light-shielding edge defining the second light-transmitting opening; and
the first spacer edge and the first light-shielding edge have a first offset distance in a direction parallel to the main surface of the base substrate, and the second spacer edge and the second light-shielding edge have a second offset distance in the direction parallel to the main surface of the base substrate,
wherein
the first offset distance is greater than the second offset distance; or
a slope angle of the light-shielding layer is greater than or equal to a slope angle of the spacer layer.

21-23. (canceled)

24. The display panel according to claim 20, wherein
first exiting light and second exiting light that are respectively obtained after light emitted from the first light-emitting region and the second light-emitting region passing through the optical adjustment layer and the antireflection layer have a first luminance attenuation value and a second luminance attenuation value at a nonzero-degree viewing angle, respectively, wherein
the first luminance attenuation value is a percentage of a difference between a luminance of the first exiting light at the nonzero-degree viewing angle and an initial luminance of the first exiting light at a zero-degree viewing angle to the initial luminance,
the second luminance attenuation value is a percentage of a difference between a luminance of the second exiting light at the nonzero-degree viewing angle and an initial luminance of the second exiting light at a zero-degree viewing angle to the initial luminance; and
at a same viewing angle, the first luminance attenuation value is greater than the second luminance attenuation value.

25-35. (canceled)

36. A display device, comprising the display panel according to claim 1.
